(19) United States
(12) Patent Application Publication
(10) Pub. No.: US 2013/0061910 A1
(43) Pub. Date: Mar. 14, 2013

(54) Concentrating Solar Photovoltaic-Thermal System

(71) Applicants: Gilad ALMOGY, Palo Alto, CA (US); Ratson Morad, Palo Alto, CA (US); Gad Rosenfeld, Los Altos, CA (US); Amir Bar, Sunnyvale, CA (US); Radu Raduta, Mountain View, CA (US)

(72) Inventors: Gilad ALMOGY, Palo Alto, CA (US); Ratson Morad, Palo Alto, CA (US); Gad Rosenfeld, Los Altos, CA (US); Amir Bar, Sunnyvale, CA (US); Radu Raduta, Mountain View, CA (US)

(73) Assignee: Cogenra Solar, Inc., Mountain View, CA (US)

(21) Appl. No.: 13/607,570

(22) Filed: Sep. 7, 2012

Related U.S. Application Data
(63) Continuation of application No. 12/788,048, filed on May 26, 2010.
(60) Provisional application No. 61/181,235, filed on May 26, 2009.
(60) Provisional application No. 61/249,151, filed on Oct. 6, 2009.

(51) Int. Cl. H01L 31/058; F24J 2/12; F24J 2/30

(52) U.S. Cl. 136/248; 126/714; 126/643; 126/640; 126/694

(57) ABSTRACT

Systems, methods, and apparatus by which solar energy may be collected to provide heat, electricity, or a combination of heat and electricity are disclosed herein.

### CROSS-REFERENCE TO RELATED APPLICATIONS

This application is a Continuation of U.S. patent application Ser. No. 12/788,048 filed May 26, 2010 and entitled CONCENTRATING SOLAR PHOTOVOLTAIC-THERMAL SYSTEM, which claims benefit of priority to U.S. Provisional Patent Application No. 61/181,235, titled “System and Method for Maximizing Output Value of a Solar System,” filed May 26, 2009, and to U.S. Provisional Patent Application No. 61/249,151, titled “Concentrating Solar Photovoltaic-Thermal System,” filed Oct. 6, 2009. Each of U.S. patent application Ser. No. 12/788,048, No. 61/181,235, and No. 61,249,151 is incorporated herein by reference in its entirety.

### FIELD OF THE INVENTION

The invention relates generally to the collection of solar energy to provide electric power, heat, or electric power and heat.

### BACKGROUND

Alternate sources of energy are needed to satisfy ever increasing world-wide energy demands. Solar energy resources are sufficient in many geographical regions to satisfy such demands, in part, by provision of electric power and useful heat.

### SUMMARY

Systems, methods, and apparatus by which solar energy may be collected to provide a combination of heat and electricity are disclosed herein.

In one aspect, a solar energy collector concentrates solar radiation onto a solar energy receiver comprising solar cells (e.g., PV or photovoltaic cells). The solar cells are cooled and maintained at a desired operating temperature by a heat transfer fluid (coolant) which collects heat from the solar cells. The solar energy collector provides an electrical power output as well as a heat output via the heated heat transfer fluid. The flow rate of heat transfer fluid through the solar energy collector, and the temperature of heat transfer fluid introduced into the collector, may be controlled to maximize a total value of electrical and heat output by the solar energy collector. In some variations, heat transfer fluid may be chilled/and or stored prior to introduction into the solar energy collector. In some variations, heated heat transfer fluid output from the solar energy collector may be stored for subsequent use. The terms “heat transfer fluid” and “coolant” are used interchangeably throughout this specification.

In some variations of this aspect, a flow rate of the heat transfer fluid may be reduced or an initial temperature of the heat transfer fluid increased to increase the value of the collected heat. Additionally, or alternatively, a flow rate of the heat transfer fluid may be increased or an initial temperature of the heat transfer fluid decreased to increase the electric power output. The flow rate, the initial temperature, or the flow rate and the initial temperature of the heat transfer fluid may be changed, for example, in response to a signal from a purchaser of the electric power output, in response to an increase in the value of the electric power output, in response to a signal from a purchaser of the heat output, or in response to a increase in the value of the collected heat. The flow rate, the initial temperature, or both the flow rate and the initial temperature of the heat transfer fluid may be adjusted, for example, at least daily, or at least hourly, to maximize a total value of the electrical output and heat collected.

In some variations of this aspect, heat transfer fluid heated by passage through the receiver may be further heated with additional solar radiation without producing electricity from the additional solar radiation.

In some variations of this aspect, the flow rate of the heat transfer fluid through the receiver is controlled such that the heat transfer fluid is heated during a single pass through the receiver to a desired operating temperature for a thermal application.

In some variations of this aspect, heat transfer fluid is cooled, stored, and dispatched to the receiver to cool the solar cells at a time when doing so increases the total value of electrical power output and heat collected from the solar cells. In such variations, the cooled and stored heat transfer fluid may be dispatched to the receiver, for example, in response to a signal from a purchaser of the electric power requesting additional electric power or in response to an increase in the value of the electric power output.

In another aspect, a method for collecting solar energy comprises cooling a heat transfer fluid to below a first temperature and storing the cooled heat transfer fluid. The method also comprises concentrating solar radiation onto a solar energy receiver comprising solar cells that convert at least some of the solar radiation to electricity, and introducing a heat transfer fluid at a second temperature, greater than the first temperature, into the receiver. The heat transfer fluid is flowed through the receiver to collect heat from the solar cells, and exits the receiver at a third temperature greater than the second temperature. Stored heat transfer fluid at the first temperature is dispatched to the receiver to decrease the temperature of the solar cells to below the second temperature and thereby boost their electrical power output. The stored heat transfer fluid at the first temperature may be dispatched to the receiver, for example, in response to a signal from a purchaser of the electric power output or in response to a change in the value of the electric power output.

In some variations of this aspect, the method may comprise transferring heat in the heat transfer fluid at the third temperature to a thermal application, and ceasing heat transfer to the thermal application upon dispatch to the receiver of heat transfer fluid at the first temperature.

During its passage through the receiver, heat transfer fluid dispatched a the first temperature may be heated to a fourth temperature, lower than the third temperature. Heat transfer fluid at the fourth temperature may be stored and then, for example, subsequently further heated to a higher temperature desired for a thermal application, or cooled to a lower temperature (e.g., to about the first temperature) and later dispatched again to the receiver.

In another aspect, a method for collecting solar energy comprises concentrating solar radiation onto a solar energy receiver comprising solar cells that convert at least some of the solar radiation to electricity, flowing a heat transfer fluid through the receiver to collect heat from the solar cells, and controlling the flow rate of the heat transfer fluid through the receiver such that the heat transfer fluid is heated during a single pass through the receiver from a first temperature on entering the receiver to, on exiting the receiver, a second temperature desired for a thermal application. The second temperature may be, for example, greater than about 65° C., greater than about 75° C., or greater than about 85° C.

In some variations of this aspect, after being heated in the receiver, the heat transfer fluid is stored. In some such variations, during operation heat transfer fluid exiting the receiver is introduced into an initially empty or substantially empty storage vessel, which it may subsequently fill. In such variations, heat transfer fluid in the storage vessel may be available at the desired temperature from the outset of filling the storage vessel, in contrast to methods in which a stored volume of heat transfer fluid is gradually heated over time by repeated passage through a solar energy collector.

In some variations of this aspect, heat from the heat transfer fluid is transferred to a second fluid (e.g., water) via a conventional heat exchanger, for example. In some of these variations, the second fluid, heated to about the second temperature through heat exchange with the working fluid, may be stored as just described for the heat exchange fluid.

In other variations of this aspect, heat from the heat transfer fluid is transferred to a second fluid, which is then introduce at about the second temperature into an upper portion of a first storage vessel. Some of the second fluid is withdrawn from a lower portion of the first storage vessel, at a temperature lower than the second temperature, and introduced into an upper portion of a second storage vessel. Some of the second fluid is withdrawn from a lower portion of the second storage vessel at a yet lower temperature, heated to about the second temperature by heat transfer from an additional quantity of heat transfer fluid heated in the receiver, and then reintroduced into the upper portion of the first storage vessel. In this manner, a quantity of the second fluid may be maintained at about the second temperature in an upper portion of the first storage vessel. Second fluid may be withdrawn from the upper portion of the first storage vessel for use in a thermal application. Second fluid returned from the thermal application at a reduced temperature may be introduced into the lower portion of the second storage vessel.

In another aspect, a solar energy collector comprises a first (photovoltaic-thermal or PVT) portion including solar cells cooled by a heat transfer fluid, and an attached (e.g., integral) second (thermal) portion in which the heat transfer fluid is heated by solar energy concentrated by the collector but which lacks solar cells. When located downstream in the heat transfer fluid path from the PVT portion, in some variations the thermal portion of the solar energy collector may be used to heat the heat transfer fluid to temperatures of increased commercial value but at which, for example, the solar cells would not operate efficiently.

In some variations, the solar energy collector of this aspect may be configured and oriented so that it includes such a thermal portion that captures concentrated solar radiation only in a particular portion of the year (e.g., winter). This may allow for capture of thermal energy while avoiding the expense of solar cells that would be illuminated only during that particular portion of the year.

In some variations, the solar energy collector of this aspect may be configured and oriented so that it includes such a thermal portion that is illuminated by concentrated solar radiation for much of the year but is not so illuminated in a particular portion (e.g., winter) of the year. Since the thermal portion lacks solar cells, this may avoid seasonal variations in illumination of solar cells that could degrade the overall electric power performance of the collector.

In another aspect, a solar energy collector comprises a photovoltaic-thermal collector including solar cells cooled by a heat transfer fluid, and a physically separate second (thermal) collector in which the heat transfer fluid is further heated by solar energy concentrated by the collector but which lacks solar cells. This arrangement may also allow heating of the heat transfer fluid to temperatures of increased commercial value but at which, for example, the solar cells would not operate efficiently.

In some variations, a plurality of such PVT collectors may be coupled to a plurality of downstream thermal collectors to increase the temperature of the heat transfer fluid output from the PVT collectors. Heat transfer fluid temperature and flow rate into the PVT collectors may be controlled to control the temperature of heat transfer fluid output from the PVT collectors. The flow rates of heat transfer fluid from the PVT collectors to the thermal collectors may be controlled to control the temperature of heat transfer fluid that the thermal collectors output. In some variations, heat transfer fluid may flow from a single PVT collector to a single thermal collector or to a plurality of thermal collectors. Similarly, a single thermal collector may receive heat transfer fluid from only a single PVT collector, or from a plurality of PVT collectors. Any suitable heat transfer fluid flow path from PVT collectors to thermal collectors may be used.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1A shows a block diagram of a solar energy collection system.

FIG. 1B shows a block diagram of a controller that may be used, for example, in the solar energy collection system of FIG. 1A.

FIG. 2 shows a block diagram of an example low temperature coolant source.

FIG. 3 shows a block diagram of another example low temperature coolant source.

FIG. 4 shows a block diagram of an array of photovoltaic-thermal collectors.

FIG. 5 shows a block diagram of an array of photovoltaic-thermal collectors with local storage of chilled and heated coolant.

FIGS. 6A-6C show block diagrams of photovoltaic-thermal collectors having additional attached thermal collector portions.

FIG. 7 shows a block diagram of a photovoltaic collector comprising a photovoltaic-thermal collector portion fluidly coupled to a physically separate thermal collector portion downstream in a coolant path.

FIG. 8 shows a block diagram of a plurality of photovoltaic-thermal collectors fluidly coupled to a plurality of physically separate thermal collectors downstream in a coolant path.

FIG. 9 shows a block diagram illustrating use of a heat exchanger to transfer heat from a photovoltaic-thermal collector to a thermal application.

FIG. 10 shows a block diagram illustrating use of heat from a photovoltaic-thermal solar energy collector to heat a feed stream to a reverse osmosis system.

FIGS. 11A and 11B show block diagrams illustrating use of heat from a photovoltaic-thermal solar energy collector in waste water treatment.

FIG. 12 shows an example trough photovoltaic-thermal collector.

FIG. 13 shows another example trough photovoltaic-thermal collector.

FIG. 14 shows an example linear Fresnel photovoltaic-thermal collector.

FIG. 15 shows an example dish photovoltaic-thermal collector.

FIG. 16 shows another example trough photovoltaic-thermal collector.

FIG. 17 shows another example trough photovoltaic-thermal collector.

FIG. 18 shows another example linear Fresnel photovoltaic-thermal collector.

FIG. 19 shows another example linear Fresnel photovoltaic-thermal collector.

FIGS. 20A-20C show an example of a coolant cooling system heat exchanger located beneath a photovoltaic-thermal collector reflector.

FIG. 21 shows another example of a coolant cooling system heat exchanger located beneath a photovoltaic-thermal collector reflector.

FIG. 22 shows an example local cooling circuit.

FIG. 23 shows an example coolant path through two adjacent PVT receivers.

FIG. 24 shows an example system in which may be implemented a boost mode, during which stored chilled coolant is dispatched to a PVT collector to boost electric power output.

FIGS. 25A-25D show additional examples in which heat collected by solar energy collectors is stored and/or transferred to a thermal application.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “substantially parallel” and to encompass minor deviations from parallel geometries rather than to require that parallel rows of reflectors, for example, or any other parallel arrangements described herein be exactly parallel.

Disclosed herein are systems, methods, and apparatus by which solar energy may be collected to provide electricity, heat, or a combination of electricity and heat. For convenience and clarity, a solar energy collection system is first described. Uses for and components of the solar energy collection system are subsequently further described under separately labeled headings. This organization of the description is not meant to be limiting. Any suitable variations of the disclosed solar energy collection system, including any suitable combination of components, may be used for any suitable application.

### Solar Energy Collection System

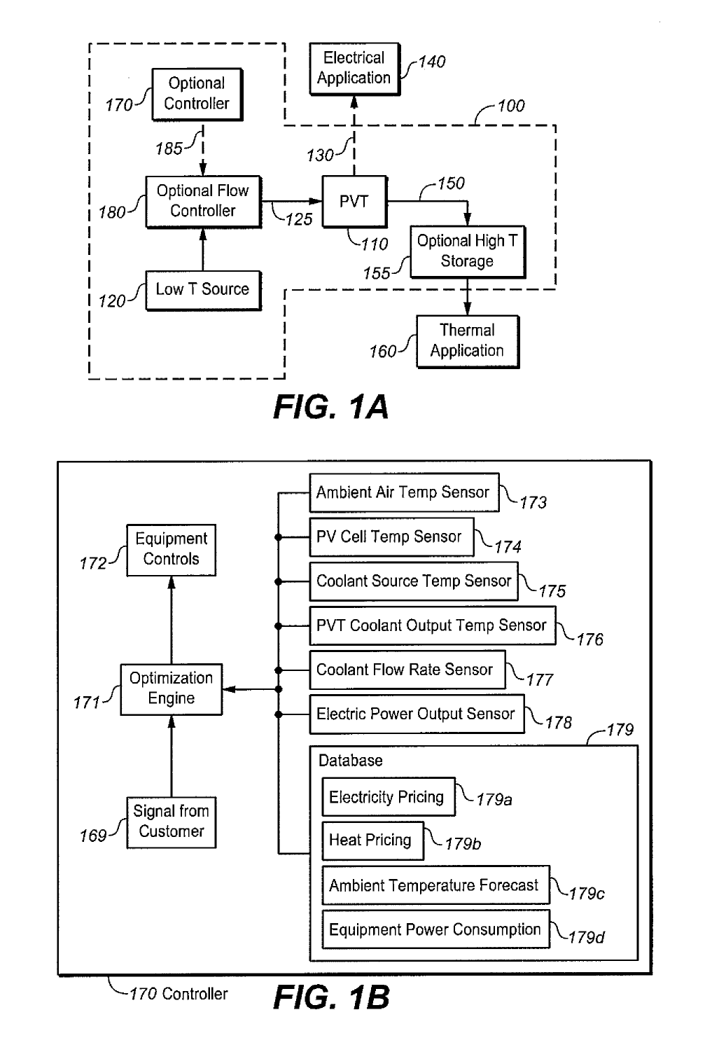

Referring initially to FIG. 1A, a solar energy collection system 100 includes a photovoltaic-thermal (PVT) solar energy collector 110 and a low temperature coolant source 120. PVT collector 110 comprises mirrors, lenses, or other optics that concentrate solar radiation onto photovoltaic cells or other devices, also included in PVT collector 110, that convert the collected solar radiation to electricity. Coolant from coolant source 120 passes through PVT collector 110 to collect heat from, and thus cool, the photovoltaic cells or other such solar energy-to-electricity converting devices in PVT collector 110. PVT collector 110 provides an electric power output 130 that may be provided to an electrical application 140 and a heat (e.g., heated coolant) output 150 that may be provided to a thermal application 160. Heated coolant 150 output from PVT collector 110 may be stored in optional high temperature storage 155 prior to being provided to thermal application 160, in some variations.

Particular examples of PVT collectors, coolant sources, coolant storage, and coolant systems are described in more detail below. Generally, any suitable PVT collector, coolant source, storage, or system described herein, known to one of ordinary skill in the art, or later developed, may used in any suitable combination in solar energy collection system 100.

Referring again to FIG. 1A, in some variations solar energy collection system 100 comprises a controller 170 that controls a flow control mechanism (flow controller) 180 regulating flow of coolant from coolant source 120 to PVT collector 110. Increasing the flow rate of coolant through PVT collector 110 and/or decreasing the temperature of the coolant input to PVT collector 110 tends to decrease the temperature of the solar cells or other solar conversion devices included in PVT 110 as well as decrease the temperature of the coolant output from PVT 110. Typically, the efficiency of solar (e.g., PV) cells decreases with increasing operating temperature. Hence, increasing the flow rate of coolant through PVT collector 110, or decreasing the temperature of coolant input to PVT collector 110, tends to increase the electrical power output by PVT collector 110.

The value of electricity provided by PVT 110 depends on the amount of electrical power it generates and the price for which that power may be sold, which in turn may depend on the particular application or use for the power. For example, where electrical application 140 is the electrical grid, in some markets the price for the power provided may depend on the time of day. The value of the heat captured in heated coolant 150 output from PVT 110 typically increases with the temperature of the heated coolant and depends on the particular application or use for the heat. Hence, the value of the electrical power generated by PVT 110 and the heat captured by PVT 110 may vary in an opposite manner as the temperature and flow rate of the coolant passing through PVT 110 are increased or decreased.

In some variations, controller 170 determines a temperature and/or a flow rate of coolant 125 into PVT collector 110 that maximizes the sum of the values of the electrical power 130 generated and the heat (e.g., heated coolant 150) collected, and controls flow controller 180 via signal 185 to provide that flow rate. Controller 170 may determine the optimal coolant temperature and coolant flow rate, for example, based in part on the price for which the electricity may be sold, the value of the collected heat as a function of temperature, the temperature of the coolant from coolant source 120, the ambient air temperature, the temperature of the photovoltaic cells and/or coolant 150 output from PVT collector 110, and a measure of the electric power output 130. In some variations, the temperature of the coolant in coolant source 120 can be reduced with, for example, radiative or convective cooling systems and/or refrigeration systems (see more detailed discussion below), at some cost. In such variations, the controller may also use the cost of cooling the coolant in determining an optimal coolant temperature and/or flow rate through PVT collector 110.

The maximized value of heat and electricity may be, for example, a maximization of current time value. In other variations, such as for example those for which there is a cost to the chilled coolant or in which heat collected in PVT collector 110 may be stored (e.g., in high temperature coolant storage 155), the maximized value of heat and electricity may be a projected value for a period during which chilled coolant and/or stored heat might be optimally dispensed.

Referring now to FIG. 1B, in one variation controller 170 comprises an optimization engine 171 providing instructions to equipment controls 172. Optimization engine 171 utilizes (e.g., real-time) information from, for example, sensors 173-178 as well as database 179 to instruct equipment controls (e.g., flow controllers, cooling equipment) 172 to, for example, control coolant flow rates and/or coolant temperatures to achieve, for example, desired electrical power and/or heat outputs.

In the illustrated example, sensors 173-178 sense, respectively, the ambient air temperature, the temperature of photovoltaic cells in PVT 110, the temperature of coolant at coolant source 120, the temperature of heated coolant 150 output from PVT 110, the flow rate of coolant through PVT 110, and the electric power output 130 from PVT 110. Database 179 comprises, for example, data on real time and/or future electricity pricing, data on real time and/or future heat pricing, data on forecasted ambient air temperatures, and data on power consumed by equipment (e.g., flow controllers, cooling equipment) controlled by controller 170 or otherwise contributing to the cost of producing electric power output 130 and/or heat output 150. In other variations, controller 170 may utilize any other suitable measurements or data.

In some variations, controller 170 responds to a signal 169 from a customer (e.g., an electric power utility or a process heat customer) requesting or demanding, for example, an increase in electric power output or a change in temperature or volume of heated coolant delivered to the customer. Controller 170 may respond to a demand for increased electricity output, for example, by increasing a flow rate of coolant, decreasing the temperature of coolant introduced into the solar collector, or both. In some such variations, in response to a demand for increased electric power output, controller 170 may initiate a “boost mode”, described in more detail below, in which stored chilled coolant (e.g., at a temperature of about 15° C. or less) is dispensed to the PVT collector in addition to, or instead of, a higher temperature coolant (e.g., at a temperature of 25° C. or more). This action increases (boosts) the electric power output of the system during the period in which the chilled coolant is dispensed. In other variations, controller 170 may respond to a demand for increased heat output or increased temperature by decreasing a flow rate of coolant through the PVT collector (thus increasing the temperature at the output) or by introducing (e.g., previously stored) warmer coolant into the PVT collector for further heating.

Methods by which controller 170 determines an optimal temperature and/or flow rate of coolant through PVT collector 110 and determines optimal times and manners for chilling coolant and/or storing chilled coolant may include, but are not limited to, those disclosed in U.S. Provisional Patent Application Ser. No. 61/181,235. Controller 170 may be implemented, for example, in any suitable combination of software, hardware, or firmware. Flow controller 180 (and all other flow controllers referred to in this description) may comprise, for example, any suitable single one or combination of valves, remotely operable valves, and pumps.

Any suitable coolant (e.g., heat exchange fluid) may be used to cool PVT collector 110. Suitable coolants may include, but are not limited to, water, ethylene glycol, water-alcohol mixtures, water-ethylene glycol mixtures, and thermal (heat exchange or heat transfer) oils. If the coolant is not suitable for direct utilization by thermal application 160, a heat exchanger may be used to transfer heat from heated coolant 150 to thermal application 160 as described, for example, further below.

The temperature of coolant 125 entering PVT collector 110 may be, for example, about 5° C., about 10° C., about 15° C., about 20° C., about 25° C., about 30° C., about 35° C., about 40° C., about 45° C., about 50° C., about 55° C., about 60° C., about 65° C., about 75° C., about 80° C., about 85° C., about 90° C., about 95° C., or about 100° C. The temperature of coolant 150 leaving PVT collector 110 may be, for example, increased compared to its input temperature by about 5° C., about 10° C., about 15° C., about 20° C., about 25° C., about 30° C., about 35° C., about 40° C., about −45° C., about 50° C., about 55° C., about 60° C., about 65° C., about 75° C., about 80° C., about 85° C., about 90° C., about 95° C., or about 100° C.

In some variations, coolant 125 enters PVT collector 110 at a temperature between about 10° C. and about 25° C., and leaves PVT collector 110 as heated coolant stream 150 at a temperature between about 5° C. and about 10° C. higher (e.g., at a temperature between about 15° C. and about 35° C.). These temperature ranges may optimize performance of photovoltaic cells in PVT collector 110.

In other variations, coolant 125 enters PVT collector 110 at a temperature between about 10° C. and about 25° C., and leaves PVT collector 110 as heated coolant stream 150 at a temperature between about 25° C. and about 95° C. higher (e.g., at a temperature between about 50° C. and about 120° C.). These temperature ranges may provide higher value heat and may allow use of ambient temperature (e.g., low cost) coolant. In one variation coolant 125 enters PVT collector 110 at between about 10° C. and about 25° C., and leaves PVT collector 110 as heated coolant stream 150 at a temperature of about 70° C. or 80° C. In another variation 125 enters PVT collector 110 at between about 10° C. and about 25° C., and leaves PVT collector 110 as heated coolant stream 150 at a temperature of about 120° C.

In other variations, coolant 125 enters PVT collector 110 at a temperature between about 50° C. and about 100° C., and leaves PVT collector 110° C. as heated coolant stream 150° C. at a temperature between about 10° C. and about 30° C. higher (e.g., at a temperature between about 60° C. and about 130° C.). These temperature ranges may provide yet higher value heat and also may allow use of coolant returned from a thermal application (e.g., a customer) after use, or heat recovered with a heat exchanger from coolant returned from a thermal application (e.g., a customer) after use.

In variations in which the coolant comprises water and is heated to temperatures near to or above 100° C., coolant systems (e.g., conduits, flow controllers) should be configured or selected to accommodate pressures that may result from conversion of a water component of the coolant to steam.

In some variations the coolant cycle utilized in solar energy collection system 100 may be an open loop cycle, in which coolant 150 leaving PVT collector 110 is not returned to the system 100. In such variations, low temperature coolant source 120 may be, or may be replenished by, an external source of water such as, for example, a water main, a well, a lake, or a river. In some other variations the coolant cycle is closed, and coolant is returned to solar energy system 100 from thermal application 160. The coolant may be returned at a sufficiently low temperature for use cooling PVT 110, or may be cooled by low temperature coolant source 120.

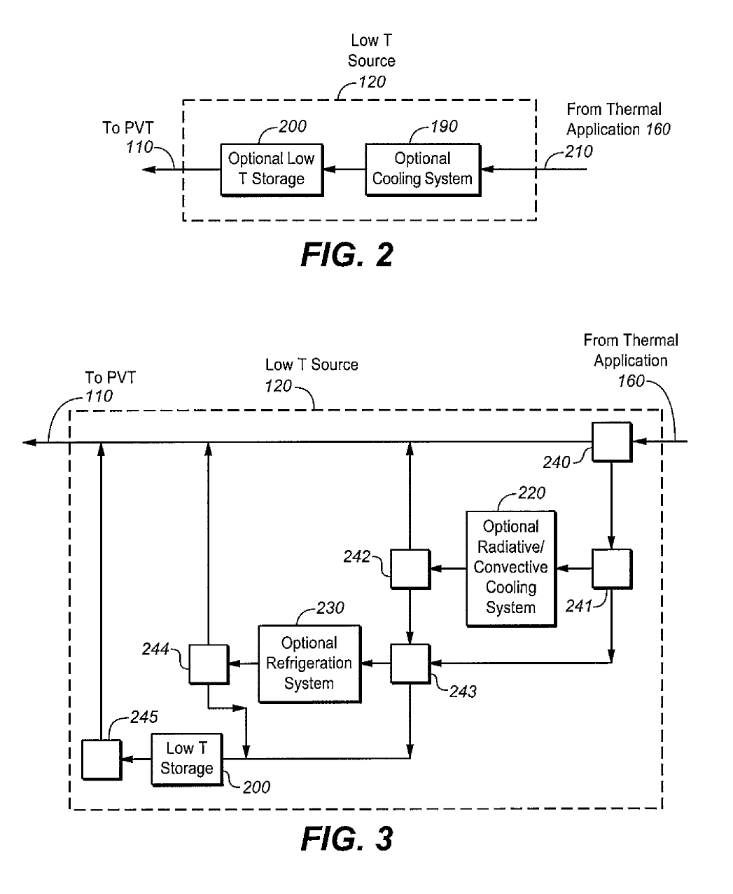

Referring now to FIG. 2, in some variations low temperature coolant source 120 may include a cooling system 190 and/or a low temperature coolant storage 200. Cooling system 190 may be controlled, for example, by controller 170 (FIG. 1A) to operate when coolant 210 entering coolant source 120 (from the thermal application as shown, or alternatively from an external source) may be advantageously cooled prior to use in solar energy collector system 100. Cooling system 190 may chill coolant 210, for example, by radiative and convective methods and/or with a refrigeration system (e.g., operating on a vapor compression or absorption refrigeration cycle). In some variations cooling system 190 is operated primarily at night, during which lower ambient temperatures may improve the efficiency of radiative and convective cooling and lower electricity prices may decrease the cost of operating a refrigeration system. The chilled coolant may be subsequently stored, for example, in low temperature coolant storage 200.

In the variations illustrated by FIG. 3, low temperature coolant source 120 may include a radiative and convective cooling system 220 and/or a refrigeration system 230. Radiative and convective cooling system 220 may chill coolant to a temperature near, but above, the ambient air temperature. Refrigeration system 230 may cool coolant to lower temperatures. Controller 170 (FIG. 1A) may determine, for example, the optimum temperature, timing, and method of chilling and/or storing coolant, and the optimum timing, temperatures, and flow rates at which to dispatch coolant to PVT 110, and control the flow controllers 240-245 accordingly.

Controller 170 may control flow controllers 240-245 to provide a variety of flow paths through low temperature coolant source 120. In some variations, coolant entering low temperature coolant source 120 bypasses cooling systems 220 and 230 and storage 200 and is instead routed to PVT 110 (FIG. 1A). In other variations, at least some of the coolant entering source 120 is directed to and stored in low temperature storage 200 for later dispatch to PVT 110. These methods may be preferred, for example, when the arriving coolant is already at a temperature significantly lower than the desired operating temperature of PVT 110.

In other variations, at least some of the coolant entering source 120 is cooled by optional radiative and convective cooling system 220 and then either directed to PVT 110 or stored in storage 200 for later dispatch to PVT 110. Storing coolant chilled in this manner may be preferred when the ambient air temperature is lower than that expected during peak electricity demand periods.

In yet other variations, at least some of the coolant entering source 120 is routed directly to and cooled by refrigeration system 230 and then either directed to PVT 110 or stored in storage 200 for later dispatch to PVT 110. Storing coolant chilled in this manner may be preferred, for example, when the ambient air temperature is close to that expected during peak electricity demand periods, and/or when the cost of operating refrigeration system 230 is low (e.g., during periods of low electricity rates).

In additional variations, at least some of the coolant entering source 120 is first cooled by convective and radiative cooling system 220, then further cooled by refrigeration system 230, then either directed to PVT 110 or stored in storage 200 for later dispatch to PVT 110. Storing coolant chilled in this manner may be preferred, for example, when the ambient air temperature is significantly lower than that expected during peak electricity demand periods and/or when the cost of operating cooling systems 220 and 230 is sufficiently low (e.g., during periods of low electricity rates.

In some variations, coolant dispatched to PVT 110 from storage 200 may be mixed with coolant that bypasses cooling systems 220 and 230 or with coolant output from either or both of cooling systems 220 and 230.

Refrigeration system 230 may be operated to chill coolant, for example, primarily at night to minimize cost. Chilled coolant in storage 200 may be dispensed to PVT collector 110 in quantities and at times, for example, for which the increase in value of the electricity generated in PVT collector 110 is greater than the cost paid to chill and store the coolant. At other times, coolant to PVT collector 110 may bypass cooling systems 220 and 230 and storage 200, or be routed through radiative and convective cooling system 190, if present, but bypass refrigeration system 230 and storage 200.

In some variations, the coolant flow rate through PVT collector 110 is maintained at a relatively low value during morning operation to conserve chilled coolant, and then increased in the afternoon to increase the electric output 130 of PVT 110. In other variations, heated coolant at a desired temperature is provided to satisfy a (e.g., morning) demand by flowing coolant through PVT collector 110 at a sufficiently slow rate, and/or by recirculating heated coolant 150 through PVT collector 110, such that the desired temperature is reached with the available (e.g., morning) solar irradiance. In another variation, coolant flow rate through PVT collector 110 is increased and/or the coolant temperature at the input to PVT collector 110 is decreased (by increased flow of stored chilled coolant, for example) in response to an increased demand for electricity.

Some variations may use (e.g., switch from another cooling method to) a “once through” cooling method to increase electric power production in response to a strong demand. In some such variations an auxiliary low temperature coolant source (e.g., city or tap water) may be used to provide coolant stream 125. This may be done, for example, by coupling the auxiliary source to supply coolant to coolant storage 200. Output heated coolant stream 150 may be either stored or disposed of (e.g., dumped) if there is insufficient storage. In other such variations an auxiliary low temperature coolant source is used to chill coolant 125 with a heat exchanger (not shown). The warm water output from the heat exchanger may be either stored or dumped if there is insufficient storage. The “once through” aspect of these variations arises from the possibility of dumping coolant from the auxiliary source after its use to cool PVT collector 110. In one example, coolant 125 at about 70° C. is further cooled to a temperature of about 20° C. to about 35° C. by heat exchange with city water at a temperature of about 20° C. This may result in about a 20% increase in electric power output. Auxiliary coolant consumption in this example may be about 2 meter³/hour for about a 0.7 kilowatt-hour increase in electric power output.

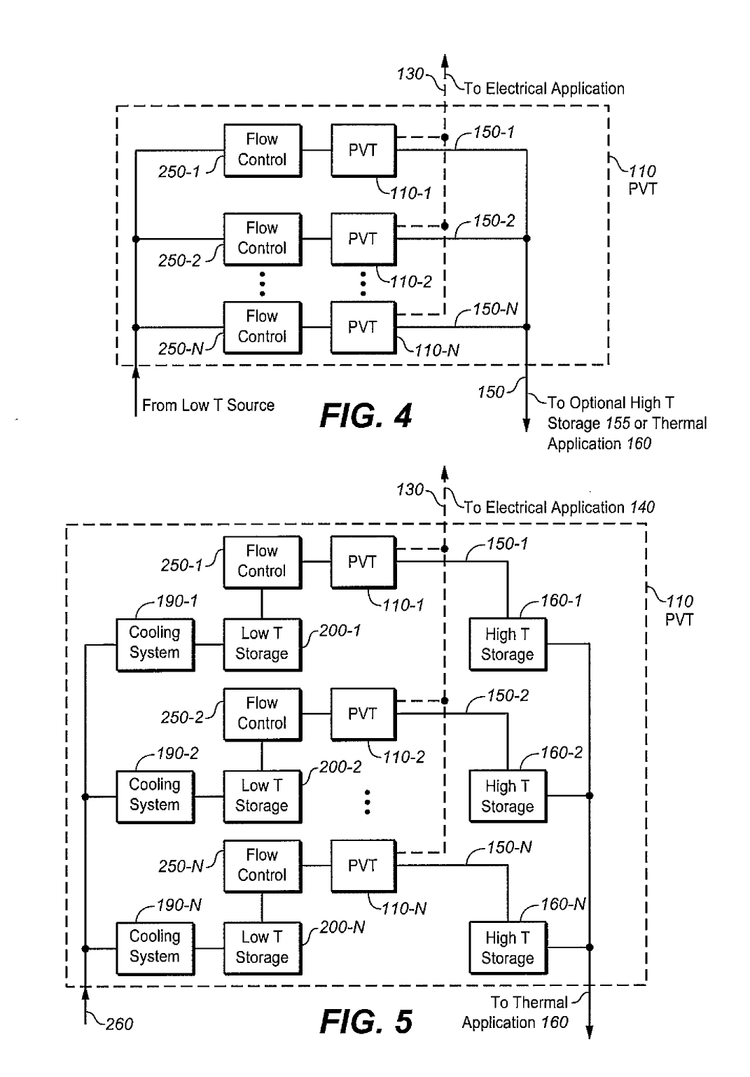

Referring now to FIG. 4, PVT 110 (FIG. 1A) may in some variations comprise a plurality of N photovoltaic-thermal collectors PVT 110-1, PVT 110-N. As described above with respect to PVT-110, each of these photovoltaic-thermal collectors comprises mirrors, lenses, or other optics that concentrate solar radiation onto photovoltaic cells or other devices that convert the collected solar radiation to electricity. The individual photovoltaic-thermal collectors PVT 110-1, PVT 110-N may be, but are not necessarily, substantially identical. Controller 170 (FIGS. 1A and 1B) may control flow controllers 250-1, 250-N to individually and independently control the flow of coolant from coolant source 120 through each of PVT-110-1, PVT 110-N. Heated coolant 150-1, 150-N output from the photovoltaic-thermal collectors may be aggregated as shown and directed to a thermal application or, as shown, to a heated coolant storage for later use in such a thermal application.

In the variations shown in FIG. 4, coolant may be chilled, stored (e.g., FIGS. 2 and 3) and distributed to PVT 110-1, PVT 110-N from an (e.g., central or shared) source 120 external to PVT 110, and coolant heated in PVT 110-1, PVT 110-N may be aggregated and stored in an (e.g., central or shared) storage 155 external to PVT 110. In some other variations chilling and storage of chilled coolant and/or storage of heated coolant output from the photovoltaic-thermal collectors may be provided locally to PVT 110-1, PVT 110-N. In the variations shown in FIG. 5, for example, coolant 260 (from an external source, or returned from a thermal application 160) is cooled and chilled locally to PVT-110-1, PVT 110-N by cooling systems 190-1, 190-N and storage 200-1, 200-N. Portions (or all) of heated coolant 150-1, 150-N may optionally be recirculated (not shown) through corresponding ones of PVT110-1, PVT 110-N and their local cooling systems and storage in some variations.

In some variations chilling and/or storage of chilled coolant is provided locally to PVT 110-1, PVT 110-N as in FIG. 5, for example, and heated coolant 150-1, 150-N is aggregated and optionally stored externally to PVT 110 as in FIG. 4, for example. In other variations chilling and/or storage of chilled coolant is provided externally to PVT 110, and heated coolant 150 output from PVT 110-1, PVT 110-N is stored locally as in FIG. 5, for example. Although FIG. 5 shows local chilling and storage of chilled coolant, and storage of heated coolant, associated on a one-to-one bases with PVT 110-1, PVT 110-N, in other variations two or more of PVT 110-1, PVT 110-N may be associated with the same local chilling of coolant, local storage of chilled coolant, and/or local storage of heated coolant.

As shown in the various figures and described above, flow through an individual PVT collector or a plurality of PVT collectors may be controlled using flow controllers such as valves and pumps, for example. The figures typically show such flow controllers positioned in the coolant flow path before a PVT collector, but such flow controllers may in addition, or alternatively, be positioned after the PVT collector or PVT collectors. For example, pumps may be positioned in the coolant flow path ahead of the PVT collectors, and valves after the PVT collectors. Coolant flow may be regulated by opening or closing valves, by changing pump speeds, or by opening or closing valves and changing pump speeds. In some variations, pump speed and valve operation (i.e., the extent to which a valve is open) are chosen to provide a desired flow rate with minimum or approximately minimum cost of pumping.

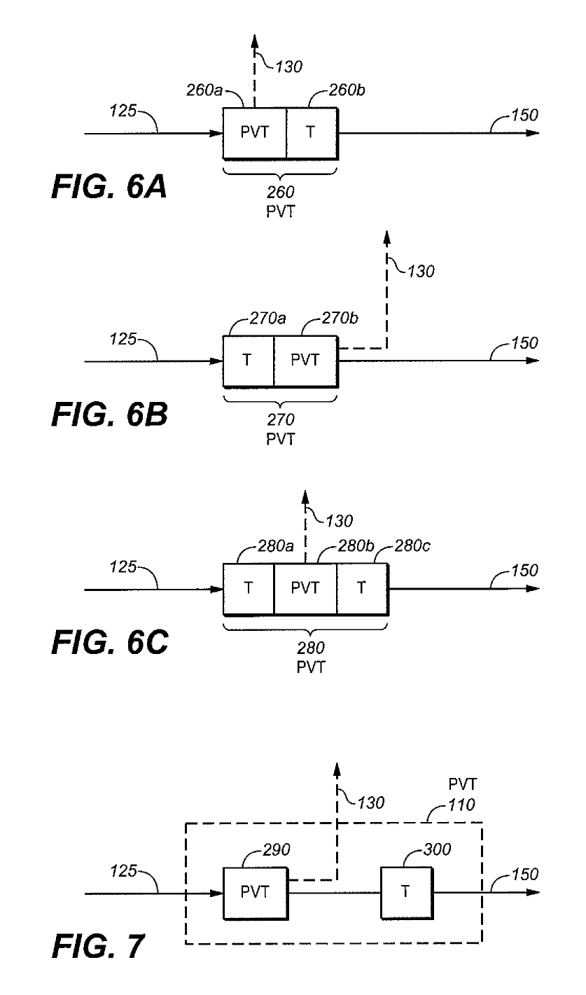

Referring now to FIGS. 6A-6C, in some variations photovoltaic-thermal collectors as used in solar energy collection system 100 (e.g., PVT 110 in FIG. 1A, PVT 110-1, PVT 110-N in FIGS. 2 and 3), for example, include one or more portions comprising PV devices or other solar radiation-to-electricity generating devices cooled by a coolant and one or more attached (e.g., integral) portions not including such solar radiation-to-electricity conversion devices but in which the coolant is heated or further heated by solar radiation. FIG. 6A, for example, shows photovoltaic thermal collector 260 comprising a PVT portion 260a and a thermal (T) portion 260b. Coolant 125 passes through PVT portion 260a, which provides an electric power output 130 and heats coolant 125, and then passes through thermal portion 260b, which further heats the coolant to provide heated coolant output 150. In FIG. 6B, photovoltaic thermal collector 270 comprises a thermal portion 270a and a PVT portion 270b. Coolant 125 initially passes through and is heated by thermal portion 270a, and then passes through PVT portion 270b which provides an electric power output 130 and further heats the coolant to provide heated coolant output 150. In FIG. 6C, photovoltaic-thermal collector 280 comprises thermal portions 280a and 280c at either end of PVT portion 280b. Coolant 125 initially passes through and is heated by thermal portion 280a, then passes through PVT portion 280b which further heats the coolant and provides electric power output 130, then passes through thermal portion 280c which further heats the coolant to provide heated coolant output 150.

Both PVT 260 and PVT 280 include coolant heating portions (260b, 280c) downstream from their PVT portions (260a, 280b) with respect to the direction of coolant flow. This allows PVT 260 and PVT 280 to operate their PVT portions at temperatures for which electricity production is efficient, and then to further heat the coolant to boost its temperature to more commercially valuable levels. In some variations, the heated coolant output by such PVT collectors may have a temperature of about 50° C., about 55° C., about 60° C., about 65° C., about 75° C., about 80° C., about 85° C., about 90° C., about 95° C., about 100° C., about 110° C., about 120° C., about 130° C., about 140° C., about 150° C., about 160° C., about 170° C., about 180° C., about 190° C., about 200° C., or above 200° C.

In addition, in some variations photovoltaic-thermal collectors utilized in solar energy collection system 100 (FIG. 1A) are linear collectors (e.g., trough or linear Fresnel collectors, see further below) in which solar radiation is concentrated by one or more linearly extending mirrors to a linear focus along a linearly extending receiver. The receiver and mirror or mirrors may be oriented substantially parallel to one another in a substantially North-South direction, with mirror(s), receiver, or mirror(s) and receiver angularly reorienting around the North-South axis during the day to track the East-West apparent motion of the sun and thereby concentrate solar radiation onto the receiver. In such variations, the linearly focused solar radiation walks in the polar direction along the receiver as the sun's altitude above the earth's equator decreases. This may result in a seasonal variation in which, during the winter, the linearly focused solar radiation walks off the polar end of the receiver and a portion of the equatorial end of the receiver is not illuminated by the concentrated solar radiation.

Walk off from the polar end of the receiver reduces the electric power output and the thermal output of the system in a season (Winter) in which at least the thermal output may be of enhanced value. Walk off from the equatorial end of the receiver resulting in some solar cells being only weakly illuminated (or not illuminated) may severely degrade electric power output from the system because the current through series connected solar cells is limited by the lowest current (most weakly illuminated) cell.

In part to address these problems, in some variations photovoltaic-thermal collectors having both PVT and thermal portions (as illustrated, for example in FIGS. 6A-6C) and having a linear configuration and focus are arranged in a North-South orientation so that seasonal walk off as described above results in linearly concentrated solar radiation walking at least partially off of a PVT portion and onto a thermal portion at the polar end of the collector. This can allow for capture of thermal energy that would otherwise be lost without the expense of solar cells that would be illuminated for only a portion of the year. Similarly, in some variations such photovoltaic-thermal collectors are arranged so that seasonal walk off as described above results in linearly concentrated solar radiation at least partially walking off of a thermal portion at the equatorial end of the collector onto a PVT portion. This can accommodate seasonal walk off without a degradation of electrical performance resulting from unilluminated photovoltaic cells. In variations in which the photovoltaic-thermal collector has thermal portions at both ends (e.g., FIG. 6C), the collector may be arranged so that seasonal walk results both in walk off from an equatorial thermal portion onto a PVT portion and from the PVT portion onto a polar thermal portion.

Referring now to FIG. 7, in some variations photovoltaic-thermal collectors used in solar energy collection system 100 (e.g., PVT 110 in FIG. 1A, PVT-110-1, PVT 110-N in FIGS. 2 and 3), for example, comprise separate PVT 290 and thermal 300 collectors arranged in series along a coolant path. PVT 290 comprises photovoltaic or other solar radiation-to-electricity converting devices cooled by coolant 125 and providing electric power output 130. Thermal collector 300 further heats the coolant that has passed through PVT 290 to provide heated coolant output 150. Similarly to the variations shown in FIGS. 6A and 6B, this arrangement allows PVT 290 to operate at temperatures for which electricity production is efficient, and then boosts the temperature of the coolant in thermal collector 300 to more commercially valuable levels. In some variations, the heated coolant output by such PVT collectors may have a temperature of about 50° C., about 55° C., about 60° C., about 65° C., about 75° C., about 80° C., about 85° C., about 90° C., about 95° C., about 100° C., about 110° C., about 120° C., about 130° C., about 140° C., about 150° C., about 160° C., about 170° C., about 180° C., about 190° C., about 200° C., or above 200° C.

PVT 290 and thermal collector 300 may have optically similar configurations (e.g., both linear focus trough or both linear Fresnel) or be of different optical configuration (e.g., linear focus for PVT 290, point focus for thermal collector 300).

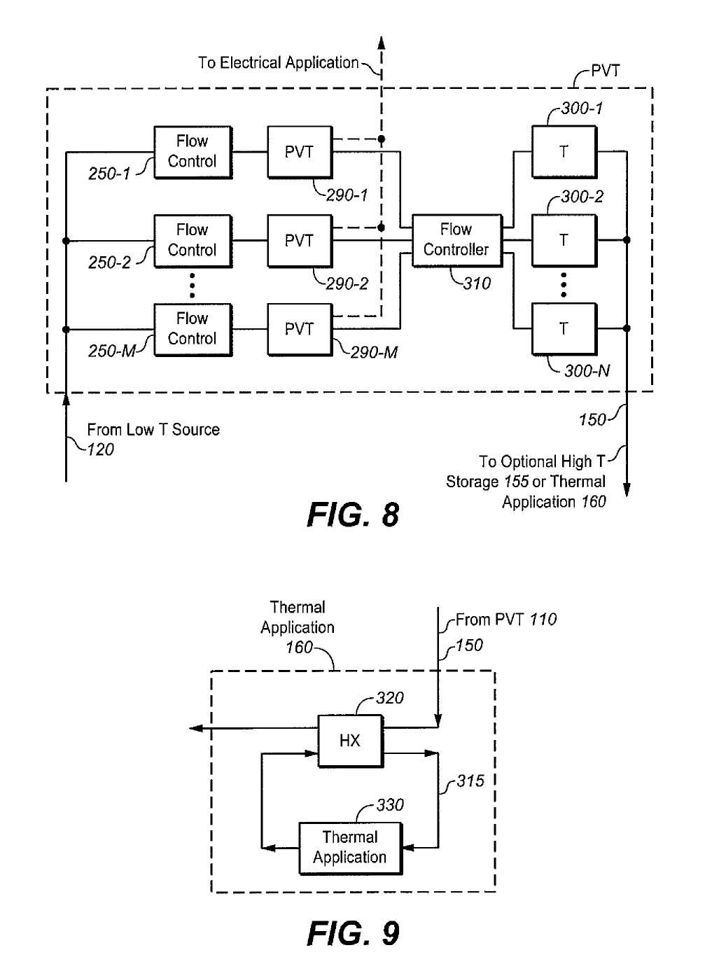

The arrangement of FIG. 7, in which the series coupled PVT 290 and thermal collector 300 are physically separate, allows additional flexibility in coupling photovoltaic-thermal collectors to (booster) thermal collectors. Referring to FIG. 8, for example, in some variations M PVT collectors 290-1, 290-M are coupled to N booster thermal collectors 300 by flow controller 310. In different variations, M=N, M<N, or M>N. In some variations, controller 170 (FIG. 1A) controls flow controllers 250-1, 250-M to control, e.g., the temperature of the coolant output by PVT collectors 290-1, 290-M, and separately controls the flow of heated coolant from the PVT collector's to booster thermal collectors 300-1, 300-N to control the temperature of the coolant output by the booster thermal collectors.

Coolant may be routed from the PVT collectors to the booster thermal collectors in any suitable manner. For example, coolant may be routed from a single PVT collector to a single thermal collector receiving coolant only from the corresponding PVT collector. Coolant from two or more PVT collectors may be aggregated and routed to a lesser number of (e.g., a single one of) the thermal collectors. Coolant from a single PVT collector may be routed to two or more thermal collectors. Any combination of these example routing schemes may also be used.

In FIG. 8 the coolant is shown drawn from an external coolant source 120 and the heated coolant output from thermal collectors 300-1, 300-N is aggregated as coolant output 150 and sent to optional external storage 155 or to thermal application 160. In other variations, coolant chilling and/or storage may be provided locally to the PVT collectors in any of the manners described above, and/or heated coolant output from thermal collectors 300-1, 300-N may be stored locally to the thermal collectors in any of the manners described above.

### Thermal and Electrical Applications

As noted above, electric power provided by solar energy collection system 100 (FIG. 1A) may be delivered to the electric power transmission grid for sale, for example, to a utility operating such grid. Such distribution would likely require, for example, use of an inverter and other conventional equipment and methods to convert the electric output of system 100 to a form (e.g., AC of appropriate voltage) for distribution on the grid. Such conventional conversion process are known to one of ordinary skill in the art and hence not necessarily illustrated in the figures. In other variations, electric power provided by solar energy collection system 100 may be used locally by an application and/or customer near which solar energy collection system 100 is located. Such local applications and/or customers may or may not require conversion of the electrical output of solar energy collection system 100 to another form, but if necessary such conversion can also generally be accomplished by conventional methods known to one of ordinary skill in the art and not necessarily illustrated in the figures.

The thermal output of solar energy collection system 100 (e.g., heated coolant stream 150) may also be advantageously delivered for use by an application or customer near which solar energy collection system 100 is located, particularly because long-distance transport or distribution of heat may be difficult. In some variations, heated coolant 150 output from solar energy collection system 100 is not suitable for direct utilization by a thermal application. Referring to FIG. 9, in such variations heat from heated coolant 150 may be transferred via a conventional heat exchanger 320 to another fluid 315 for use in a thermal application 330. Coolant 150 exiting from heat exchanger 150 may be routed back to, e.g., coolant source 120 of solar energy collection system 100 (FIG. 1A).

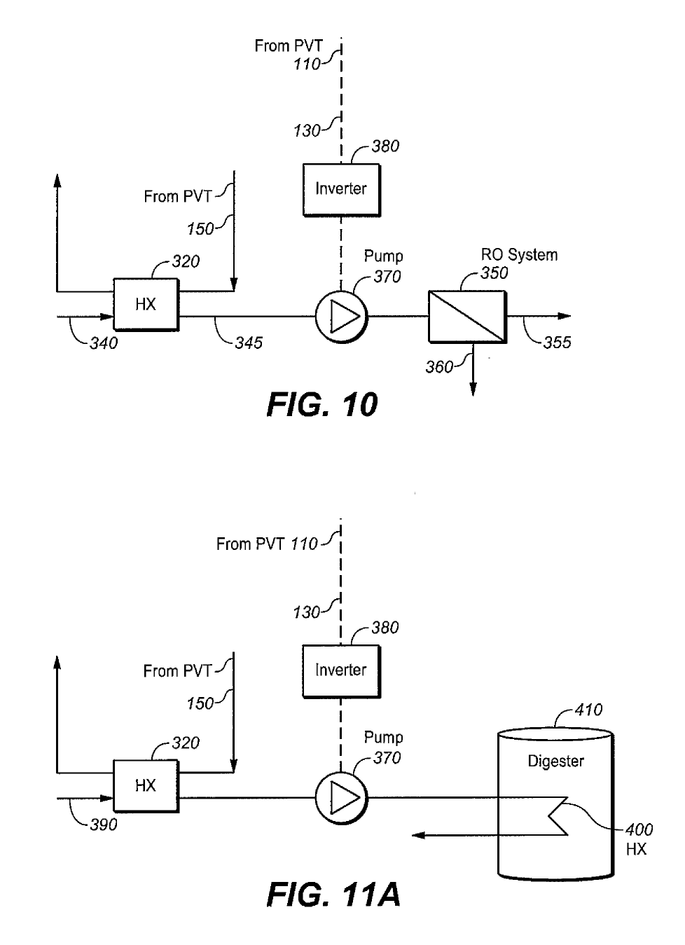

Referring now to FIG. 10, in some variations the thermal output and, optionally, electric output of solar energy collection system 100 may be advantageously used in reverse osmosis (RO) water purification systems. In such variations solar energy collection system 100 may be co-located with the reverse osmosis system. Reverse osmosis is a conventional process by which impure water is purified by passing the impure water under pressure through a membrane which rejects impurities. In the example shown in FIG. 10, feed water 340 to reverse osmosis system 350 passes through heat exchanger 320 in which it is warmed by heat delivered by heated coolant 150 from solar energy collection system 100 (FIG. 1A). The heated feed water 345 is then directed to RO system 350 (comprising one or more RO membranes, not shown) which separates the feed water into purified 355 and rejected 360 streams. In some variations, feed water 340 is sea water or brine, and RO system 350 desalinates the feed water to provide desalinated water in purified stream 355 and salt water in rejected stream 360.

Heating feed water 345 as illustrated in FIG. 10 may increase the flow rate of purified stream 355 through RO system 350 and thus improve the efficiency of and reduce the cost of the RO process. Prior to such heating, feed water 345 may have a temperature, for example, of about 10° C. to about 40° C., in some variations about 14° C., in some variations about 15° C. to about 28° C. In some variations, feed water 345 is heated by heat exchange with heated coolant 150 to increase the temperature of feed water 345 (initially at the temperatures, or in the temperatures, provided above) by about 5° C., about 10° C., about 15° C., about 20° C., or more than about 20° C.

Optionally, heated feed water may be pumped to RO system 350 and pressurized by pump 370 powered by electrical output 130 of solar energy collection system 100. As necessary, electrical output 130 may be converted by optional inverter 380 and any other necessary conventional conversion apparatus to a form suitable for use by pump 370. Electrical output 130 of solar energy collection system may advantageously be used to power other electrical components of RO system 350.

Feed water 340 may comprise, for example, sea water, brackish water, waste water, or a mixture of any thereof.

In another variation heat exchanger 320 is not used and, instead, feed water 340 to RO system 350 is directed through solar energy conversion system 100, in which it is heated and output as heated coolant 150, then routed back to RO system 350 as heated feed water stream 345.

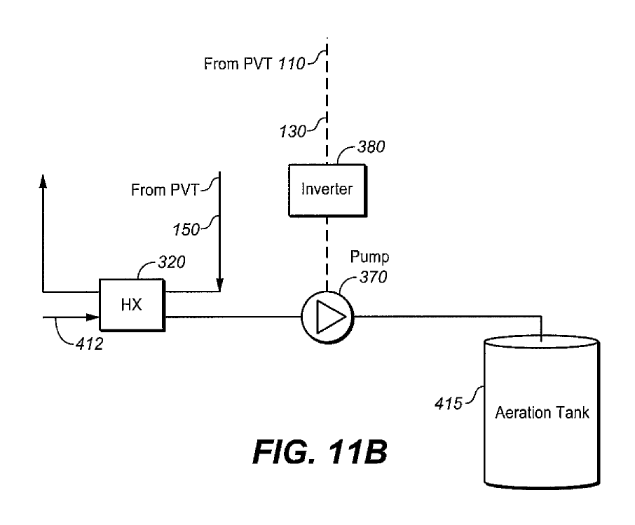

Referring now to FIGS. 11A and 11B, in some variations the thermal output and, optionally, electric output of solar energy collection system 100 may be advantageously used in waste water treatment systems. In such variations solar energy collection system 100 may be co-located with the waste water treatment system. In the example shown in FIG. 11A, heat exchanger 320 transfers heat from heated coolant 150 output from solar energy collector system 100 (FIG. 1A) to a heat exchange fluid 390. Heat exchange fluid 390 is then routed through a second heat exchanger 400 in a digester 410 to transfer heat to digester 410 and its contents. Digester 410 may be, for example, a component of a larger waste water treatment system (not shown).

Digester 410 may, for example, contain sludge separated from waste water in an earlier treatment step. Heat collected in solar energy collection system 100 and delivered to digester 410 may be used to accelerate or facilitate otherwise conventional processes for reducing pathogens in such sludge. Such processes may include, for example, composting at temperatures ≧55° C., thermophilic aerobic digestion at temperatures of about 55° C. to about 60° C., heat drying of the sludge at temperatures >80° C., and heat treatment of liquid sludge at temperatures >180° C. Hence, in some variations solar energy collection system 100 provides heated coolant 150 at temperatures 55° C., >80° C., or >180° C. as necessary to deliver heat to digester 400 at temperatures suitable for the corresponding treatment processes.

Although the example illustrated in FIG. 11A utilizes two heat exchangers, in other variations heat exchanger 320 is not used and, instead, heated coolant 150 from solar energy collection system 100 is passed through heat exchanger 400 to deliver heat to digester 410 and its contents.

As shown in FIG. 11A, in some variations electrical output 130 from solar energy collection system 100 may be used to power a pump 370 directing heat exchange fluid through heat exchanger 400 in digester 410. Electrical output 130 of solar energy collection system 100 may also advantageously be used to power other electrical components of a waste water treatment system.

In the example shown in FIG. 11B, heat exchanger 320 transfers heat from heated coolant 150 output from solar energy collector system 100 (FIG. 1A) to waste water influent 412 to an aeration tank 415. The influent may be heated to a temperature, for example, of about 20, about 25° C., about 30° C., about 35° C., about 40° C., or more than about 40° C. In the aeration tank, waste water is aerated by blowers (not shown), for example, to transfer oxygen into the waste water. Bacteria in the aeration tank utilize the oxygen as they consume biodegradable material in the waste water. Heating the influent as described may increase the efficiency of aeration and hence reduce energy costs for aeration.

In some variations electrical output 130 from solar energy collection system 100 may be used to power a pump 370 directing influent 412 to aeration tank 415.

Thermal and electrical output from PVT collector 110 may be utilized in other applications, as well. Additional examples may include providing electricity and hot water to residential users, dairy farms, hospitals, cheese factories, wineries, and laundry facilities. Such solar hot water may be used, for example, for space heating, washing, or process heat applications. In some variations, hot water having a temperature greater than about 70 C, or greater than about 90 C, is provided to drive one or more adsorption and/or absorption chillers. Such chillers may be used, for example, to provide solar powered air conditioning or refrigeration. In some variations, thermal output from a PVT collector is used to preheat water, or another liquid, prior to further heating by a fossil-fueled burner or boiler or by other conventional heating. The further heating may be performed, for example, by a customer or in a customer's thermal application.

### PVT Collectors

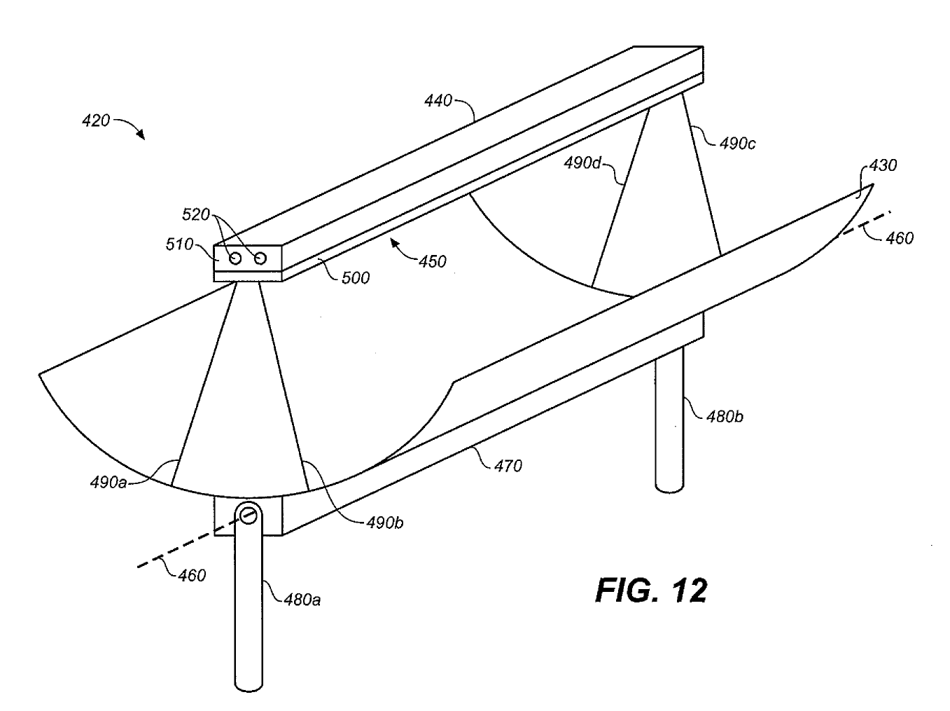

Any suitable photovoltaic, thermal, or photovoltaic-thermal collectors may be used in or with the systems, methods, and apparatus disclosed herein. Any suitable solar energy receivers may be used in such solar energy collectors. Suitable solar energy collectors and receivers may include, but are not limited to, those disclosed in U.S. patent application Ser. No. 12/712,122, titled “Designs for 1-Dimensional Concentrated Photovoltaic Systems,” filed Feb. 24, 2010; U.S. patent application Ser. No. 12/622,416, titled “Receiver for Concentrating Photovoltaic-Thermal System,” filed Nov. 19, 2009; U.S. patent application Ser. No. 12/774,436, titled “Receiver for Concentrating Photovoltaic-Thermal System,” filed May 5, 2010; and U.S. patent application Ser. No. 12/781,706, titled “Concentrating Solar Energy Collector,” filed May 17, 2010; all of which are incorporated herein by reference in their entirety. Suitable thermal (e.g., booster) receivers or portions of receivers may also include, for example, vacuum tube thermal energy receivers (comprising one or more vacuum insulated tube absorbers) and flat plate thermal energy receivers (e.g., including coolant tubes within, in front of, or behind the flat plate). Such receivers may optionally comprise secondary optics focusing concentrated solar radiation onto an absorber. Such suitable photovoltaic, thermal, and photovoltaic-thermal collectors may also include, but are not limited to, those described below with respect to FIGS. 12-19.

Referring to FIG. 12, in one variation a photovoltaic-thermal trough collector 420 comprises a linearly extending trough shaped reflector 430 and a linearly extending solar receiver 440 with a lower surface 450 located at approximately a linear focus of and facing reflector 430. Reflector 430 and receiver 440 are arranged to maintain their relative positions as they rotate together around a pivot axis 460. By such rotation reflector 430 can be oriented to reflect solar radiation from the sun to lower surface 450 of receiver 440. Reflector 430 may have, for example a parabolic or approximately parabolic curvature in a direction transverse to the pivot axis 460.

One of ordinary skill in the art will recognize that solar trough collectors are known in the art, and that features of the support structure shown in FIG. 12 locating receiver 440 with respect to receiver 430 and accommodating their joint rotation about axis 460 are intended as schematic illustrations representing numerous configurations known in the art.

In the particular example of FIG. 12, reflector 430 is attached to and supported above a longitudinally extending support 470 (e.g., a torque tube) that is pivotably attached to support posts 480a and 480b. Receiver 440 extends linearly along and parallel to trough shaped reflector 430 and is attached to and supported above reflector 430, at approximately the linear focus of reflector 430, via supports 490a-490d. Support posts 480a and 480b support collector 420 above any underlying surface (e.g., the ground) at a sufficient height to allow angular rotation about pivot axis 160 as described above.

Receiver 440 comprises photovoltaic cells 500 (or other solar radiation-to-electricity converting devices) located along lower face 450 onto which solar radiation concentrated by reflector 430 is incident. Photovoltaic cells 500 are in thermal contact with substrate 510, through which coolant channels 520 extend longitudinally through the receiver. Coolant passed through coolant channels 520 collects heat from substrate 510 to thereby cool cells 500.

It should be understood that the photovoltaic-thermal receiver illustrated in FIG. 12, as well as those illustrated in subsequent figures, may be electrically and/or fluidly (for coolant flow) connected in series (e.g., end to end for liner focus collectors) to effectively provide an extended photovoltaic-thermal collector.

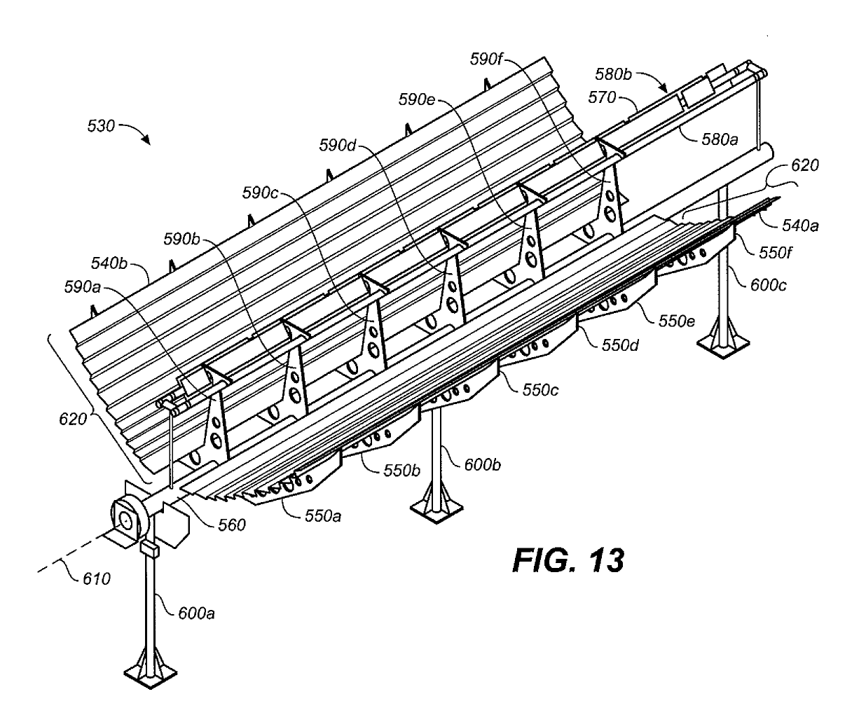

Referring now to FIG. 13, in another variation a photovoltaic trough collector 530 comprises linearly extending reflectors 540a and 540b supported by transverse ribs 550a-550f and attached thereby to longitudinally extending torque tube 560. Linearly extending receiver 570, comprising lower faces 580a and 580b forming a V-shaped cross section, is attached to and positioned above torque tube 560 by supports 590a-590f to locate its lower face 580a at approximately a linear focus of reflector 540a and to locate its lower face 580b at approximately a linear focus of reflector 540b.

Torque tube 560 is pivotably attached to support posts 600a-600c, allowing reflectors 540a and 540b to rotate together with receiver 570 around pivot axis 610 to orient reflectors 540a, 540b to reflect solar radiation from the sun to, respectively, lower faces 580a, 580b of receiver 570.

Similarly to receiver 440 (FIG. 12) receiver 570 comprises photovoltaic cells (or other solar radiation-to-electricity converting devices) located along faces 580a, 580b onto which solar radiation concentrated by reflectors 540a, 540b is incident. The photovoltaic cells are in thermal contact with a substrate through which coolant channels extend longitudinally through the receiver. Coolant passed through the coolant channels collects heat from the substrate to thereby cool the photovoltaic cells.

Reflectors 540a and 540b each comprise a plurality of linearly extending flat mirrors 620 supported by ribs 550a-550f to approximate a parabolic curvature. The aspect ratio (length divided by width) of flat mirrors 620 in the surface of reflectors 540a, 540b may be, for example, about 10:1, about 20:1, about 30:1, about 40:1, about 50:1, about 60:1, about 70:1, about 80:1, about 90:1, about 100:1, about 110:1, about 120:1, or more than about 120:1. In one example, mirrors 620 are about 11.1 meters long and about 0.10 meters wide (aspect ratio about 112:1). In another example, mirrors 620 are about 11.1 meters long and about 0.13 meters wide (aspect ratio about 86:1). In some variations, mirrors 620 may be assembled from shorter length mirrors, having lengths as short as about 1 meter, positioned end to end.

Although FIG. 13 shows photovoltaic-thermal concentrator 530 comprising particular numbers of receiver supports, ribs, posts, and flat mirrors, these components may be present in greater or lesser numbers than as shown.

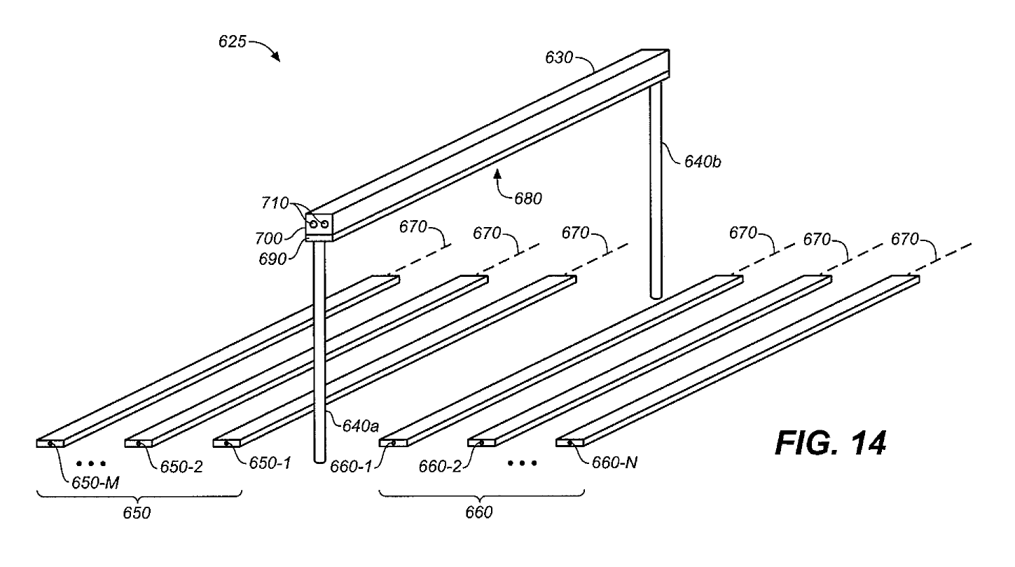

In another variation (FIG. 14), a linear Fresnel photovoltaic-thermal collector 625 comprises a stationary linearly extending receiver 630 elevated by supports 640a, 640b above reflector fields 650 and 660. Reflector fields 650 and 660 comprise, respectively, rows 650-1 to 650-M and 660-1 to 660-N of reflectors arranged parallel to and on opposite sides of receiver 630. Each of the individual reflector rows (though depicted in a horizontal orientation) is configured to rotate about a corresponding one of pivot axes 670. By such rotation the reflector rows may be oriented to reflect solar radiation from the sun to a linear focus along a lower face 680 of receiver 630. The reflectors may be flat or have, for example, parabolic or approximately parabolic curvature with focal lengths of approximately the distance from the reflector center lines to the center line of receiver lower face 680. The reflector fields may have equal or unequal numbers (M, N) of reflectors rows.

One of ordinary skill in the art will recognize that linear Fresnel collectors are known in the art, and that features of the support structures and the general arrangement of the reflectors with respect to the receiver are intended as schematic illustrations representing numerous configurations known in the art.

Similarly to receiver 440 (FIG. 12), receiver 630 comprises photovoltaic cells (or other solar radiation-to-electricity converting devices) 690 located along lower face 680 onto which solar radiation concentrated by reflectors in reflector fields 650, 660 is incident. Photovoltaic cells 690 are in thermal contact with substrate 700, through which coolant channels 710 extend longitudinally through the receiver. Coolant passed through coolant channels 710 collects heat from substrate 700 to thereby cool cells 690.

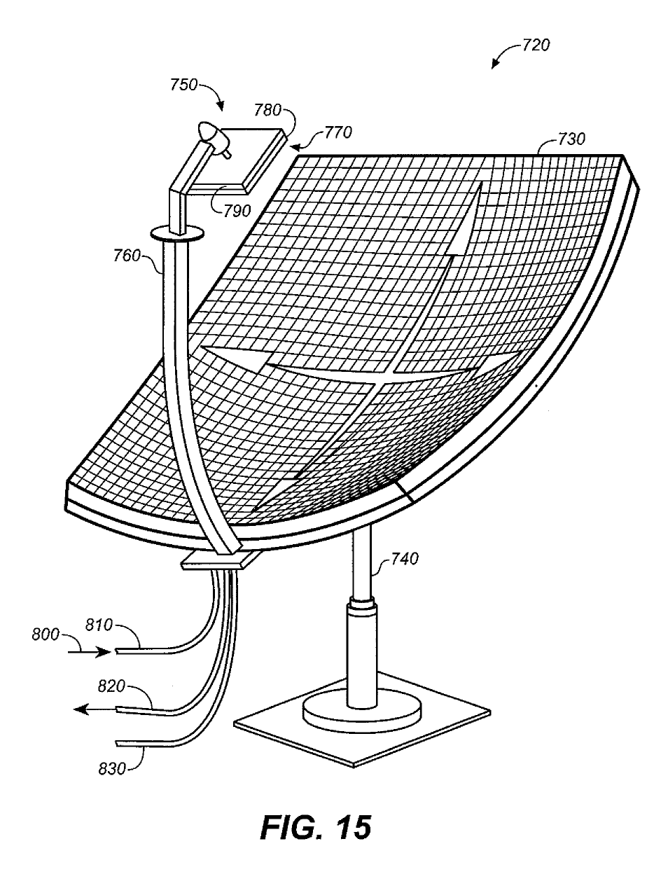

Referring now to FIG. 15, in another variation a dish photovoltaic-thermal collector 720 comprises a dish reflector 730 pivotably supported by support structure 740 allowing dish reflector 730 to be rotated about two axes to face the sun. Dish collector 720 further comprises a receiver 750 positioned by support structure 760 at approximately the focus of dish reflector 730. When oriented to face the sun, dish reflector 730 focuses solar radiation from the sun onto lower surface 770 of receiver 750.

One of ordinary skill in the art will recognize that dish collectors are known in the art, and that features of the support structures and the general arrangement of the reflector with respect to the receiver are intended as schematic illustrations representing numerous configurations known in the art.

Receiver 750 comprises photovoltaic cells (or other solar radiation-to-electricity converting devices) 780 located along lower face 770 onto which solar radiation concentrated by dish reflector 730 is incident. Photovoltaic cells 780 are in thermal contact with substrate 790, through which coolant channels (not shown) pass. Coolant 800 enters collector 720 through conduit 810, passes through the channels in substrate 790 to collect heat from substrate 790 and thereby cool the photovoltaic cells 780, and then exits collector 720 through conduit 820. Collector 720 provides electric power through conductor 830.

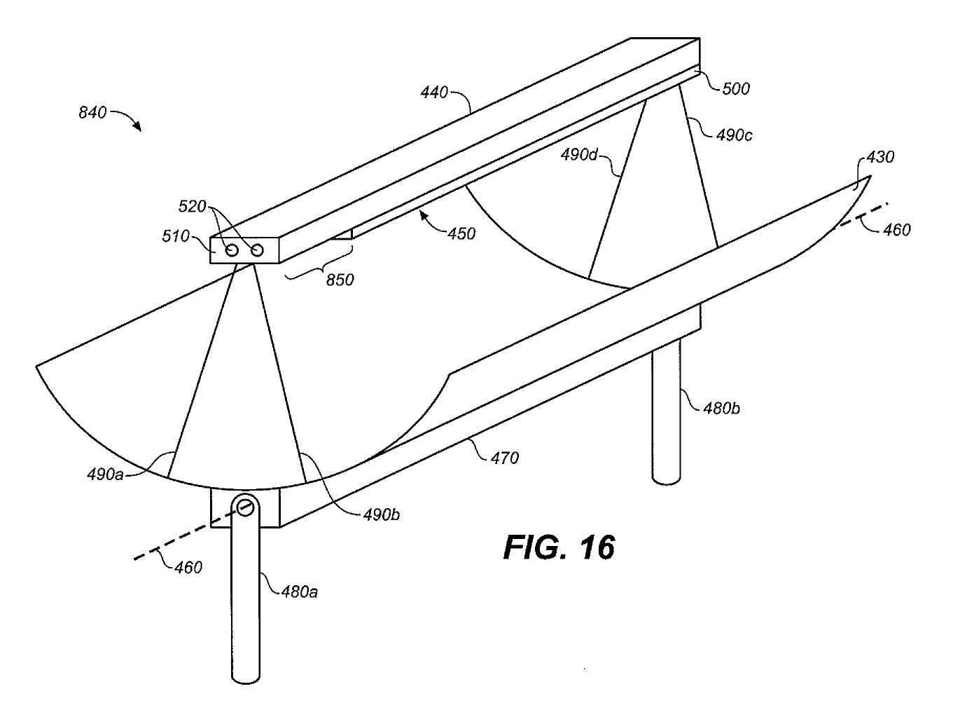

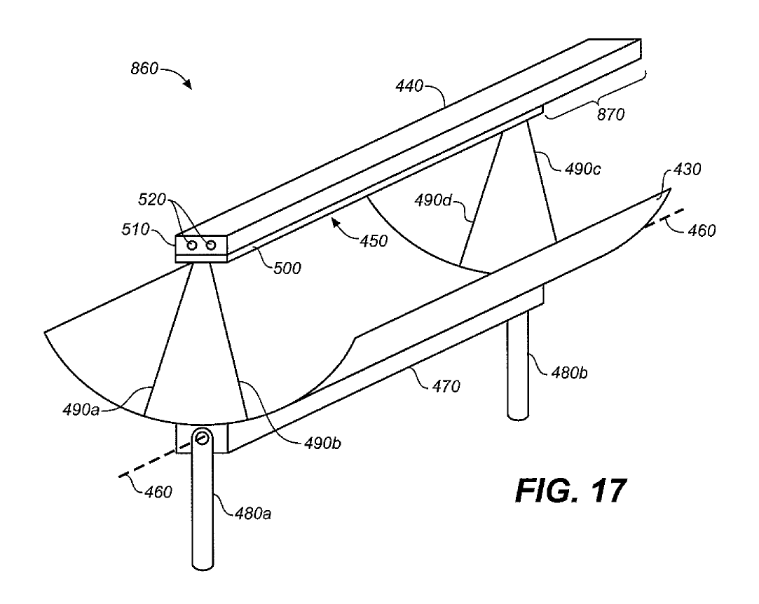

FIG. 16 shows a photovoltaic-thermal collector 840 substantially similar to collector 420 shown in FIG. 12, except that receiver 440 of collector 840 comprises a thermal portion 850 not including any solar cells. This photovoltaic-thermal collector may be used, for example, in the manner described above with respect to PVT 260 and PVT 280 (FIGS. 6A and 6B). Similarly, FIG. 17 shows a photovoltaic-thermal collector 860 also substantially similar to collector 420 and also comprising a thermal portion (870) not including any solar cells. In this variation, thermal portion 870 extends beyond the end of reflector 430. This photovoltaic-thermal collector may also be used in the manner described above with respect to PVT 260 and PVT 280. Trough collectors similar to collectors 420, 840, and 860 may have such thermal portions at each end of the receiver, as well, and be used, for example, in a manner similar to that described above with respect to PVT 280 (FIG. 6C).

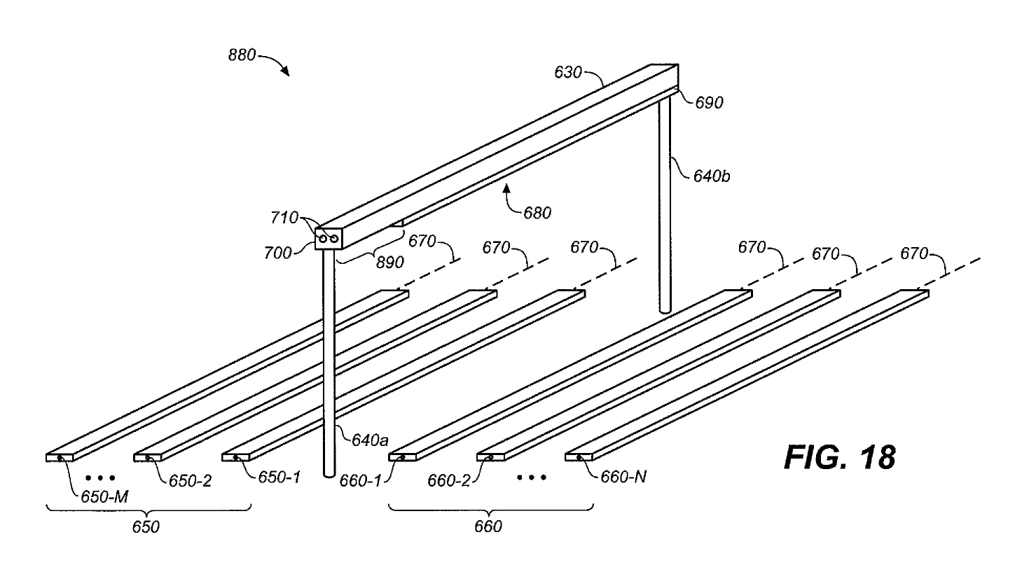

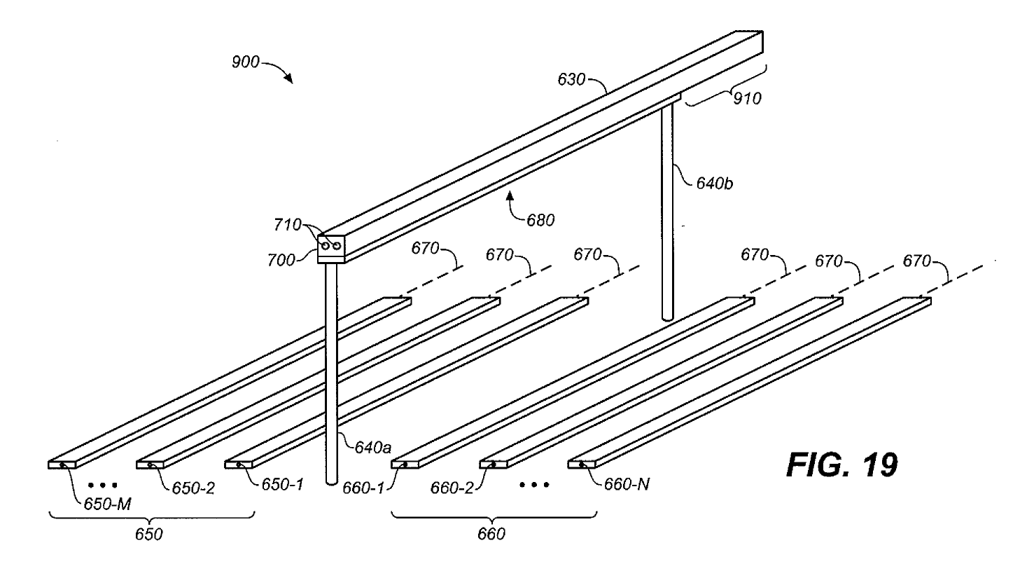

FIGS. 18 and 19 show linear Fresnel photovoltaic-thermal collectors substantially similar to linear Fresnel collector 625 (FIG. 14) and also analogous to the trough collectors shown in FIGS. 16 and 17. Receivers 630 of linear Fresnel photovoltaic-thermal collector 880 (FIG. 18) and 900 (FIG. 19) comprise, respectively, thermal portions 890 and 910 at their respective ends. In collector 900, thermal portion 910 extends beyond the ends of the reflector fields. Collectors 880 and 900 may be used, for example, in the manner described above with respect to PVT 260 and PVT 280. Linear Fresnel photovoltaic-thermal collectors similar collectors 625, 880, and 900 may have such thermal portions at each end of the receiver, as well, and be used, for example, in a manner similar to that described above with respect to PVT 280 (FIG. 6C).

Cooling, Storage, Additional example Modes of Operation

Any suitable cooling systems may be used with or in the solar energy collection systems described herein. In some variations, a central (shared) cooling system chills coolant for many (e.g., all) PVT collectors in a solar collector installation. In other variations, each PVT collector (or row or column of fluidly coupled collectors) is served by a separate (local) cooling system. In yet other variations, two or more cooling systems each serve separate groups of two or more PVT collectors or rows or columns of fluidly coupled collectors.

As noted above, some variations may utilize refrigerator systems in which coolant for the solar energy collection system is chilled using, for example, a vapor compression or absorption refrigeration cycle. Some variations may also, or instead, use evaporative cooling systems. Some variations may also, or instead, utilize cooling systems that chill coolant for the solar energy collection system by passing the coolant through a heat exchanger that facilitates radiative and/or convective transfer of heat from the coolant to the external environment (e.g., ambient air). Such cooling systems may include, for example, fin-fan systems in which fans circulate ambient air across a finned heat exchanger through which the coolant is passed. Some variations use such a forced-air cooling system shared between two or more (e.g., all) of the PVT collectors in a solar collector installation.

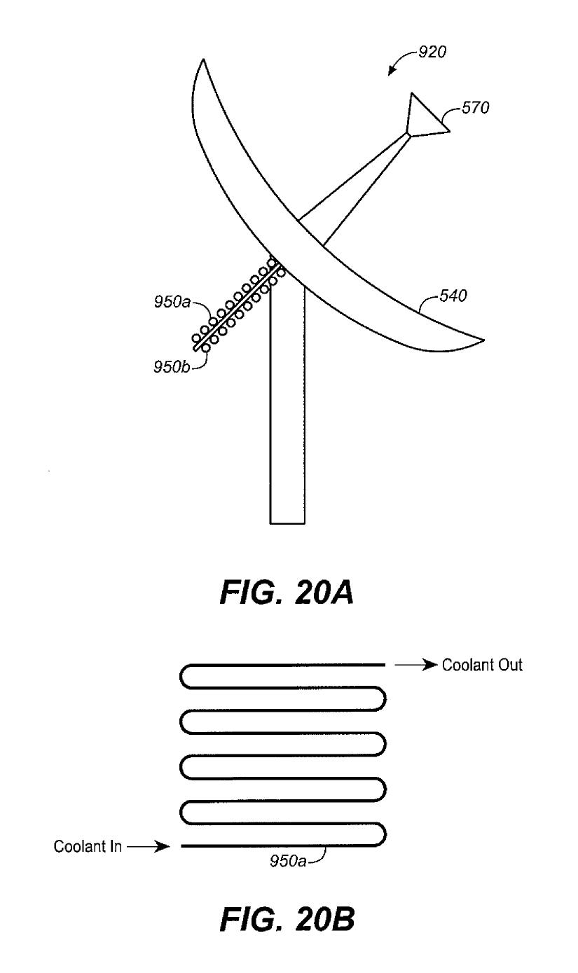

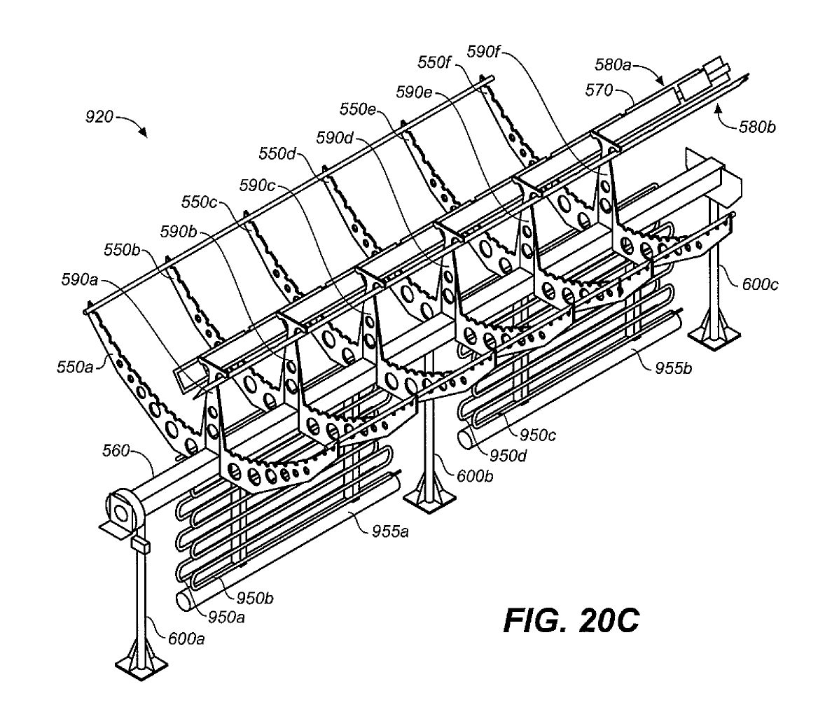

Some variations may utilize convective and/or radiative cooling systems in which the heat exchanger is located in the shade of one or more reflectors in the solar energy collection system. Referring to FIGS. 20A-20C, for example, in some variations a trough photovoltaic-thermal collector 920 (shown in profile end-on in FIG. 20A, in perspective view in FIG. 20C absent the reflector) comprises a linear receiver 570 and a trough-shaped reflector 540 configured to concentrate solar radiation onto receiver 570. PVT collector 920 also comprises heat exchangers 950a-950d located underneath reflector 540. Coolant passed through and heated by receiver 570 may be subsequently passed through heat exchangers 950a-950d to dissipate the collected heat. Each of heat exchangers 950a-950d may provide, for example, a serpentine coolant flow path (FIG. 20B) beneath reflector 540. The shaded location of heat exchangers 950a-950d may increase the rate at which the heat is transferred to the surrounding environment.

Although FIGS. 20A-20C show PVT collector 920 comprising four serpentine heat exchangers, other variations may use fewer or more heat exchangers, each of which has any suitable geometry. In the illustrated example, and in any similar variation comprising a plurality of heat exchangers, the heat exchangers may be fluidly coupled in series, in parallel, or in any suitable combination of series and parallel. Series flow paths will provide greater cooling but also an increased pressure drop.

In the example of FIG. 20C, PVT collector 920 further comprises local storage tanks 955a and 955b below the heat exchangers. Such tanks may serve as reservoirs for the local cooling system, as well as counter-weights to other portions of PVT collector 920.

Heat exchangers such as heat exchangers 950a-950b may comprise, for example, finned aluminum tube through which the coolant passes. In some such variations, the finned aluminum tube has a diameter of about 1 inch, with about 6 fins per inch, each of which is about 0.018 inches thick and about 0.5 inches tall. Suitable finned aluminum tube may be available, for example, from Ningbo Winroad Refrigeration Equipment Company, of Ningbo China.

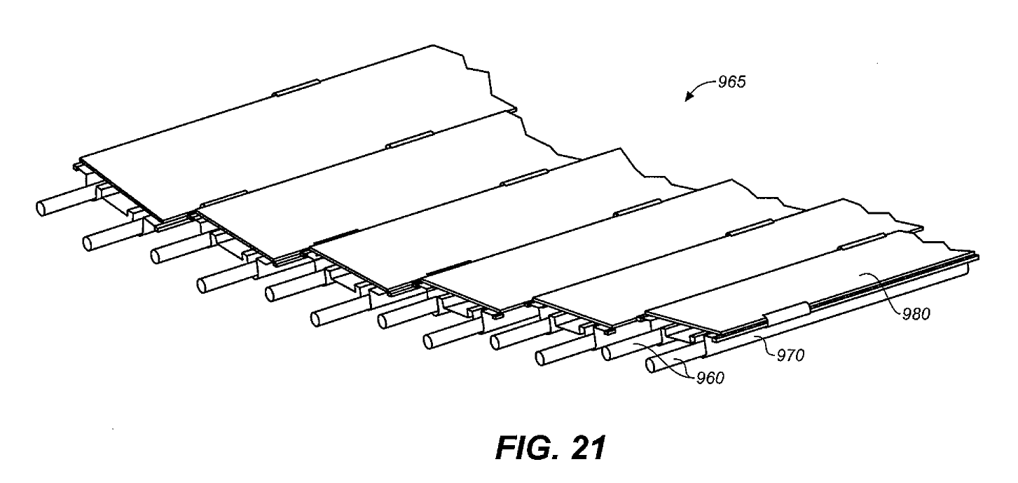

Referring now to FIG. 21, in another variation a heat exchanger comprises conduits 960 (e.g., metal or plastic tubes or hoses) attached to or suspended from a reflector structure 965 (only partially shown) by brackets 970 that clamp onto or otherwise attach to reflector or reflectors 980. In some variations, adjacent brackets 970 may interconnect to form a support structure for reflectors 980. Heated coolant output from a PVT collector of which reflector structure 965 forms a part may be passed through conduits 960 to dissipate collected heat. Conduits 960 may be interconnected in series to provide, for example, a serpentine coolant flow path beneath the reflector structure. Conduits 960 might alternatively be connected to provide two or more coolant flow paths in parallel.

Photovoltaic-thermal collector systems including local cooling systems, such as the examples of FIGS. 20A-20C and FIG. 21, may be installed and used in a modular manner, with a solar installation comprising one or more such modules. Additional modules (PVT collector and associated local cooling) may be added as desired to provide additional electrical output.

Any suitable storage vessels or systems may be used with or in the solar energy collection systems described herein to store chilled coolant for subsequent use cooling solar cells in a PVT collector, or to store heated coolant (output from a PVT collector) for subsequent use in a thermal application. Conventional plastic or metal liquid (e.g., water) storage tanks, for example, may be used in some variations. For storage local to a PVT collector or small number of PVT collectors, such tanks may have volumes ranging from about 1 m³ (meter cubed) to about 10 m³ or about 100 m³, for example. In variations in which chilled or heated coolant for many PVT collectors is stored in a single storage tank, such tanks may have volumes ranging about 100 m³ to about 1000 m3, or about 5000 m³, about 10,000 m³, about 15,000 m³, about 20,0000 m³, about 25,000 m³, or more than about 25,000 m³.

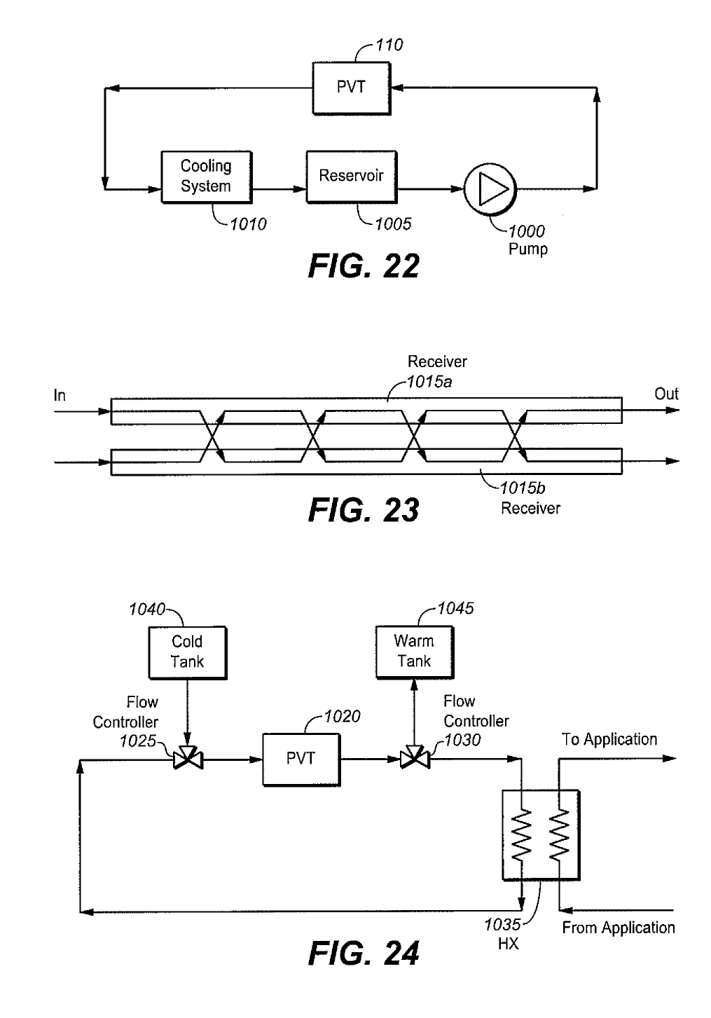

A local cooling circuit may be implemented in a variety of ways, some of which are illustrated by the coolant circuit illustrated in FIG. 22. The example of FIG. 22 includes a PVT collector 110, a pump 1000, an optional coolant reservoir 1005, and an optional cooling system 1010. In one variation, cooling system 1010 is absent. In this variation, operation begins (in the morning, for example) with reservoir 1005 containing coolant at a desired low temperature (e.g., less than about 15° C., less than about 25° C.). Pump 1000 circulates coolant from reservoir 1005 through PVT collector 110 to cool solar cells in PVT collector 110 and heat the coolant. During the course of operation, the coolant warms from its initial low temperature to higher temperatures. As the temperature of the coolant increases, the pump speed may be varied (e.g., increased) to facilitate cooling of the solar cells in the collector. The reservoir capacity may be chosen such that, typically, the final temperature at the end of a predetermined period of operation (for example, about 4 hours, about 6 hours, about 8 hours, about 10 hours, a daylight portion of a day) is less than or about equal to a predetermined temperature above which, for example, operation of the solar cells may be significantly limited. For example, the reservoir capacity may be chosen such that at the end of a such a predetermined period of operation, the temperature of the coolant is less than about 70° C., less than about 75° C., less than about 80° C., less than about 85° C., less than about 90° C., less than about 95° C., less than about 100° C., less than about 105° C., less than about 110° C., less than about 115° C., or less than about 120° C.

In another variation of the example of FIG. 22, reservoir 1005 is absent. In this example, pump 1000 circulates coolant through PVT collector 110 and than through local cooling system 1010. Local cooling system 1010 may be selected to have a predetermined cooling capacity that maintains the temperature of the coolant below, for example, about 70° C., about 75° C., about 80° C., about 85° C., about 90° C., about 95° C., about 100° C., about 105° C., about 110° C., about 115° C., or about 120° C. during the course of a predetermined period of operation. As above, such predetermined period of operation may be, for example, about 4 hours, about 6 hours, about 8 hours, about 10 hours, or a daylight portion of a day. Local cooling system 1010 may be, for example, a forced-air (e.g., fin-fan) system, a passive cooling system such as those described for example with respect to FIGS. 20A-20C and FIG. 21, or any other suitable cooling system. The cooling system may be located in shade cast by PVT collector 110, or otherwise.

In yet another variation of the example of FIG. 22, both cooling system 1010 and reservoir 1005 are present. The capacities of cooling system 1010 and reservoir 1005 may be selected to maintain coolant at or below the temperature ranges described for the other variations of this example for the periods of operation also described with respect to those other variations.

FIG. 23 shows an example coolant path through two adjacent PVT receivers 1015a and 1015b. PVT receivers 1015a and 1015b may be, for example two parallel receivers within a single PVT collector (such as those identified by reference numerals 580a, 580b in FIG. 20C, for example) or receivers in adjacent PVT collectors. In the example of FIG. 23, coolant entering receiver 1015a travels some distance along that receiver, then is routed over to receiver 1015b where it travels a further distance, then is (optionally) routed back to receiver 1015a, with further (optional) transfers back and forth between the receivers. Coolant initially entering receiver 1015b follows a similar path, in which it is routed to receiver 1015a, then optionally back and forth between the receivers. In instances in which one of the receivers receives a higher heat load than the other (e.g., because one is slightly shaded), transferring coolant between the two receivers may allow the same amount of heat to be extracted, at a higher average temperature and a lower total flow rate, as would occur if coolant flowed independently through the receivers with no cross-over of coolant between receivers.

FIG. 24 shows an example system in which may be implemented a boost mode, during which stored chilled coolant is dispatched to a PVT collector in addition to, or instead of, a higher temperature coolant. In the illustrated example, during standard operation flow controllers 1025 and 1030 route coolant to PVT collector 1020, from PVT collector 1020 to heat exchanger 1035, and then from heat exchanger 1035 back to PVT 1020. PVT 1020 may be a single PVT collector or multiple PVT collectors arranged in series, in parallel, or in series and in parallel. Heat exchanger 1035 extracts heat from the coolant output by PVT 1020, making that heat available for a thermal application. In some variations, after exiting heat exchanger 1035 coolant may be further cooled by a cooling system (e.g., a forced-air fin-fan system or a passive cooling system), not shown, before being routed back to PVT 1020. In such standard operation, coolant may enter PVT 1020 at a temperature, for example, of less than about 25° C., about 25° C., about 30° C., about 35° C., about 40° C., about 45° C., about 50° C., about 55° C., about 60° C., about 65° C., about 70° C., about 75° C., or more than about 75° C. Coolant heated in PVT 1020 may then exit PVT 1020 at a temperature increased, compared to any of the entering temperatures just listed, by about 5° C., about 10° C., about 15° C., about 20° C., or more than about 20° C. In some variations, in standard operation coolant enters PVT 1020 at about 65° C. and exits PVT 1020 at about 75° C.

Boost mode may be triggered, for example, by a human operator, by a decision made in a control system as described above, in respond to a signal from an electric power customer, or in any other suitable manner. In boost mode, flow controllers 1025 and 1030 route coolant from cold tank 1040, through PVT 1020, and then (optionally) to warm tank 1045 or (optionally) back to cold tank 1040. Cold tank 1040 may provide coolant at a temperature, for example, less than about 5° C., about 5° C., about 10° C., about 15° C., or more than about 15° C., typically providing lower temperature operation of PVT 1020 than occurs in standard operation. This lower temperature operation may enhance the efficiency of solar cells in PVT 1020, and hence boost the electrical power output of the system. In boost mode, coolant exits PVT 1020 at a temperature increased, compared to its entering temperature, by about 5° C., about 10° C., about 15° C., about 20° C., or more than about 20° C. In some variations, it is then routed by flow controller 1030 to warm tank 1045 for storage. Such “warm” coolant may be, for example, subsequently further heated (using a fossil fuel burner or boiler, or more solar energy, for example) for use in a thermal application, or chilled for further use as a coolant (e.g., to replenish cold tank 1040). In other variations warm tank 1045 is absent and, during boost mode, coolant exiting PVT 1020 is routed by flow controller 1030 back to cold tank 1040, optionally through a cooling system (not shown).

In some variations, during boost mode, previously chilled and stored coolant at a temperature of about 10° C. is routed from cold tank 1040 through PVT 1020. Coolant exiting PVT 1020 at a temperature of about 20° C. is then routed to warm tank 1045. In other variations, during boost mode, previously chilled and stored coolant at a temperature of about 15° C. is routed from cold tank 1040 through PVT 1020. Coolant exiting PVT 1020 at a temperature of about 25° C. is then routed to warm tank 1045. In either case, during standard operation, coolant at a temperature of about 65° C., for example, may be routed through PVT 1020. Coolant exiting PVT 1020 at a temperature of about 75° C., for example, is then routed to heat exchanger 1035 to deliver heat for a thermal application and then recycled through PVT1020.

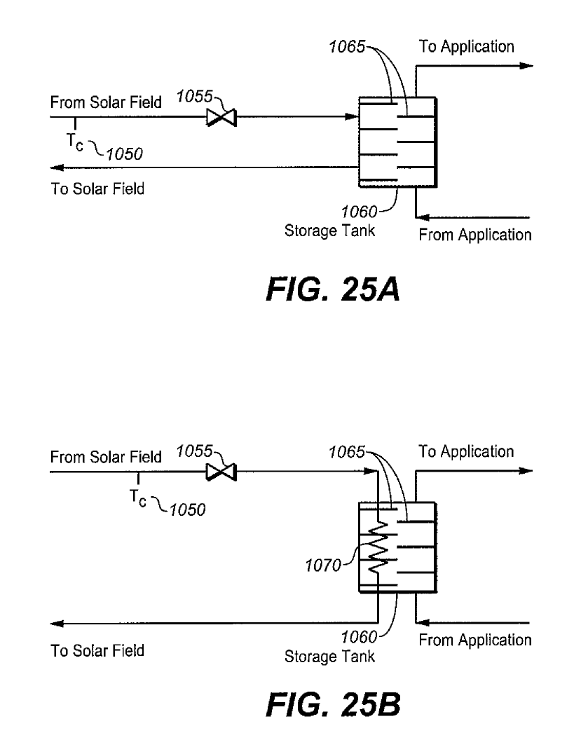

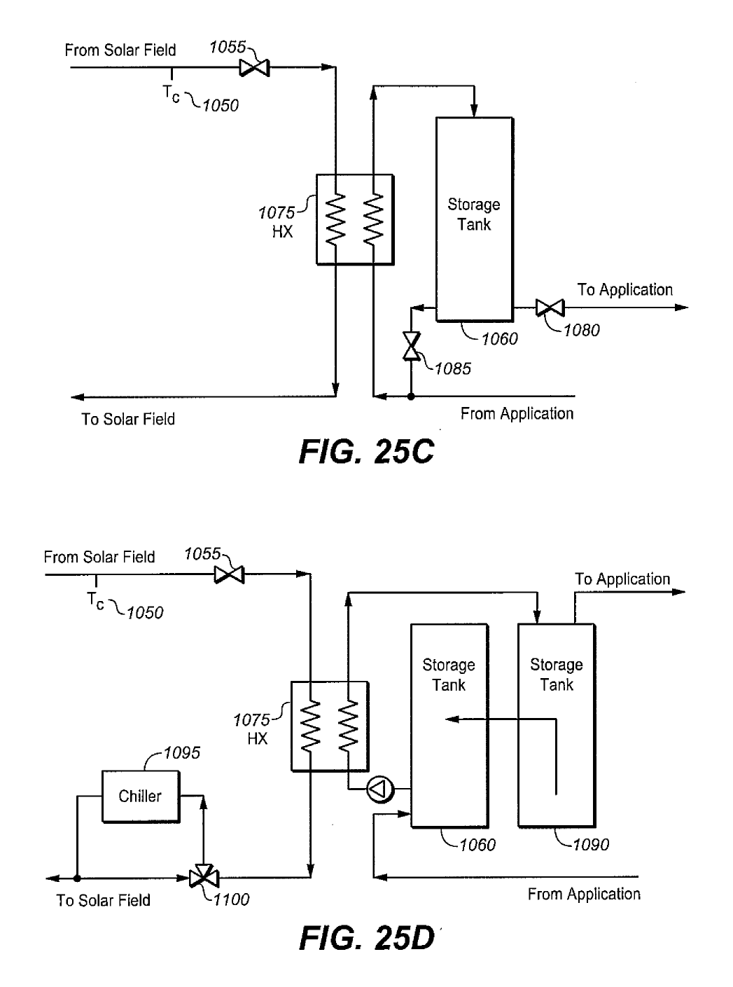

In some variations, heat is collected for a thermal application by continuously circulating a volume of coolant through a solar energy collector, or series of solar energy collectors, further heating the coolant with each pass through the collector or collectors until the coolant reaches a desired temperature. In other variations, the flow rate of coolant through a solar energy collector, or series of solar energy collectors, is controlled such that coolant reaches the desired temperature in a single pass. FIGS. 25A-25D show examples of the latter approach.

Referring now to FIG. 25A, in the illustrated example a flow controller 1055 controls the flow of coolant through a solar field (e.g., one or more than one solar energy collector) such that the coolant exits the solar field at a desired temperature as measured by an upstream temperature sensor 1050. Coolant at the desired temperature is introduced into an upper section of storage tank 1060, which is maintained in a full or substantially full condition. Coolant may be withdrawn from the upper section of the tank for use in a thermal application. Lower temperature coolant, returned from the thermal application, may be reintroduced into a lower region of tank 1060. Such lower temperature coolant may be withdrawn from the lower region of tank 1060 and recirculated through the solar field. Storage tank 1060 may comprise optional baffles 1065 designed to suppress convective heat transfer within storage tank 1060 and thus maintain a temperature difference between the top of tank 1060 (coolant at about the desired temperature, as provided from the solar filed) and the bottom of tank 1060 (coolant at about the temperature returned from the thermal application). In this example, the thermal application may receive heated coolant at the desired temperature, as produced in the solar field, without waiting for the entire volume of coolant to be brought to the desired temperature by continuous recirculation through the solar field.

The example shown in FIG. 25B is substantially similar to that of 25A, except that in the example of FIG. 25B coolant heated to a desired temperature after passage through the solar field is passed through a heat exchanger 1070 in tank 1060 to transfer heat from the coolant to another fluid used by the thermal application. In this example also, the thermal application may received heated fluid at a desired temperature quickly.

In the examples of FIGS. 25A and 25B, storage tank 1060 is maintained in a full or substantially full condition throughout operation. In the example of FIG. 25C, in contrast, storage tank 1060 fills during operation. In the latter example, coolant heated to a desired temperature after passage through the solar field is passed through a heat exchanger 1075, where its heat is transferred to a fluid to be used by the thermal application. Fluid returned from the thermal application is heated in heat exchanger 1075 to about the desired temperature, and then introduced into storage tank 1060, which it slowly fills during operation. Heated fluid may be withdrawn from a lower region of storage tank 1060 by operation of flow controller 1080, for example. If the fluid in tank 1060 cools below a desired temperature, it may be recirculated through heat exchanger 1075 by operation of flow controller 1085, for example. In this example also, the thermal application may received heated fluid at a desired temperature quickly.

FIG. 25D shows an example using cascaded storage tanks 1060 and 1070. In this example, coolant heated to a desired temperature after passage through the solar field is passed through a heat exchanger 1075, where its heat is transferred to a fluid to be used by the thermal application. Coolant exiting heat exchanger 1075 may be returned to the solar field or, optionally, directed by flow controller 1100 through a chiller or other cooling system 1095 prior to being returned to the solar field. (Such use of a cooling system is also an option in the examples of FIGS. 25A-25C, though not illustrated there). Heated fluid for the thermal application exits heat exchanger 1075 and is introduced into an upper section of storage tank 1090, which is maintained in a full or substantially full condition. Fluid may be withdrawn from the upper section of tank 1090 and directed to the thermal application. Fluid from a lower section of tank 1090 may be introduced into an upper section of storage tank 1060, which is also maintained in a full or substantially full condition. Fluid from a lower section of tank 1060 may be withdrawn and recirculated through heat exchanger 1075 for further heating. Fluid returned from the thermal application may be introduced into a lower section of tank 1060.

Cascading storage tanks 1090 and 1060 in this manner may maintain a separation between fluid at or about at the desired temperature, in an upper section of tank 1090, and fluid at increasingly lower temperatures in a lower section of tank 1090, an upper section of tank 1060, and a lower section of tank 1060. Such temperature gradient may be further enhanced and maintained by, optionally, using baffles within tanks 1060 and 1090 similarly to as described with respect to FIGS. 25A and 25B.

This disclosure is illustrative and not limiting. Further modifications will be apparent to one skilled in the art in light of this disclosure and are intended to fall within the scope of the appended claims. For instance, in the examples described herein electricity is generated by concentrating solar energy onto photovoltaic receivers, and heat is captured by a fluid used at least in part to cool photovoltaic devices in the receivers. In other variations, electricity may be generated, for example, by thermoelectric devices or other devices that convert solar radiation to electricity, and heat may be captured by a fluid used at least in part to cool such devices. Also, in some variations, electricity may be generated from solar radiation by photovoltaic, thermoelectric, or other devices without concentrating the solar radiation, and heat captured by a fluid used at least in part to cool such devices. All publications and patent applications cited in the specification are incorporated herein by reference in their entirety as if each individual publication or patent application were specifically and individually put forth herein.

What is claimed is:

1. A method for collecting solar energy with a solar energy collector, the solar energy collector comprising a reflector and a solar energy receiver including solar cells that convert at least some of the collected solar energy to electricity, the method comprising:
orienting the reflector to concentrate solar radiation onto the solar energy receiver;
flowing a liquid heat transfer fluid through the solar energy receiver to collect heat from the solar cells and thereby cool the solar cells; and
locally cooling the heat transfer fluid heated by the solar energy receiver prior to recirculating the heat transfer fluid through the solar energy receiver.

2. The method of claim 1, wherein the heat transfer fluid is locally cooled using only passive cooling that transfers the collected heat to the ambient air.

3. The method of claim 1, wherein locally cooling the heat transfer fluid comprises passing the heat transfer fluid through a heat exchanger shaded by the solar energy collector.

4. The method of claim 3, wherein the heat exchanger is attached to the reflector or to a support structure that rotates with the reflector to orient the reflector.

5. The method of claim 1, comprising locally storing the cooled heat transfer fluid prior to recirculating the heat transfer fluid through the solar energy receiver.

6. The method of claim 1, comprising locally cooling the heat transfer fluid at night and locally storing the cooled heat transfer fluid prior to recirculating the cooled heat transfer fluid through the solar energy receiver during daytime operation of the solar energy collector.

7. The method of claim 1, comprising locally storing the heat transfer fluid heated by the solar energy receiver prior to locally cooling it.

8. The method of claim 1, wherein the heat transfer fluid is locally cooled using only passive cooling with one or more heat exchangers shaded by the solar energy collector, the heat exchangers transferring the collected heat to the ambient air.

9. The method of claim 8, wherein the one or more heat exchangers are attached to the reflector or to a support structure that rotates with the reflector to orient the reflector.

10. The method of claim 1, wherein the heat transfer fluid is locally cooled using only passive cooling that transfers the collected heat to the ambient air, comprising locally storing the cooled heat transfer fluid prior to recirculating the heat transfer fluid through the solar energy receiver.

11. The method of claim 1, wherein locally cooling the heat transfer fluid comprises passing the heat transfer fluid through a heat exchanger shaded by the solar energy collector, comprising locally storing the cooled heat transfer fluid prior to recirculating the heat transfer fluid through the solar energy receiver.

12. The method of claim 11, wherein the heat exchanger is attached to the reflector or to a support structure that rotates with the reflector to orient the reflector.

13. The method of claim 1, wherein the heat transfer fluid is locally cooled using only passive cooling with one or more heat exchangers shaded by the solar energy collector, the heat exchangers transferring the collected heat to the ambient air, comprising locally storing the cooled heat transfer fluid prior to recirculating the heat transfer fluid through the solar energy receiver.

14. The method of claim 13, wherein the one or more heat exchangers are attached to the reflector or to a support structure that rotates with the reflector to orient the reflector.

15. The method of claim 1, wherein the reflector has a parabolic trough shape.

16. The method of claim 15, wherein the heat transfer fluid is locally cooled using only passive cooling with one or more heat exchangers shaded by the solar energy collector, the heat exchangers transferring the collected heat to the ambient air.

17. The method of claim 16, wherein the one or more heat exchangers are attached to the reflector or to a support structure that rotates with the reflector to orient the reflector.

18. The method of claim 16, comprising locally storing the cooled heat transfer fluid prior to recirculating the heat transfer fluid through the solar energy receiver.

19. A concentrating solar energy collector system comprising:
a solar energy collector including: a linearly extending solar energy receiver comprising solar cells and coolant channels accommodating flow of liquid heat transfer fluid through the solar energy receiver to cool the solar cells, a linearly extending reflector oriented parallel to a long axis of the receiver and fixed in position with respect to the receiver, and a linearly extending support structure supporting the receiver and the reflector and pivotally mounted to accommodate rotation of the support structure, the reflector, and the receiver about a rotation axis parallel to the long axis of the receiver to concentrate solar radiation onto the receiver with the reflector;
a cooling system positioned locally to the solar energy collector; and
a pump configured to flow a liquid heat transfer fluid through the receiver to collect heat from the solar cells and then through the cooling system to cool the heat transfer fluid prior to recirculating the heat transfer fluid through the solar energy receiver.

20. The concentrating solar energy system of claim 19, wherein the cooling system uses only passive cooling to cool the heat transfer fluid, the passive cooling transferring heat collected by the heat transfer fluid to the ambient air.

21. The concentrating solar energy system of claim 19, wherein the cooling system comprises a heat exchanger shaded by the solar energy collector.

22. The concentrating solar energy system of claim 21, wherein the heat exchanger is attached to the support structure or to the reflector.

23. The concentrating solar energy collector of claim 19, comprising local storage for the heat transfer fluid.

24. The concentrating solar energy system of claim 19, wherein the reflector comprises a plurality of linearly extending flat or substantially flat reflective elements oriented parallel to the long axis of the receiver and fixed in position with respect to each other to form a parabolic or approximately parabolic trough.

25. The concentrating solar energy system of claim 19, wherein the cooling system cools the heat transfer fluid using only passive cooling with one or more heat exchangers shaded by the solar energy collector, the heat exchangers transferring the collected heat to the ambient air.

26. The concentrating solar energy system of claim 19, wherein the cooling system cools the heat transfer fluid using only passive cooling that transfers the collected heat to the ambient air, comprising local storage for the heat transfer fluid.

27. The concentrating solar energy system of claim 19, wherein the cooling system comprises a heat exchanger shaded by the solar energy collector, comprising local storage for the heat transfer fluid.

28. The concentrating solar energy system of claim 19, wherein the cooling system cools the heat transfer fluid using only passive cooling with one or more heat exchangers shaded by the solar energy collector, the heat exchangers transferring the collected heat to the ambient air, comprising local storage for the heat transfer fluid.

29. The concentrating solar energy system of claim 28, wherein the one or more heat exchangers are attached to the support structure or to the reflector.
